(19) United States
(12) Patent Application Publication
(10) Pub. No.: US 2023/0247794 A1
(43) Pub. Date: Aug. 3, 2023

(54) ANTI-TILT IC COOLING SYSTEM BLOCK PRESSURE MOUNT ASSEMBLY

(71) Applicant: Cooler Master Co., Ltd., Taipei City (TW)

(72) Inventors: Hsiang chieh Tseng, Taipei City (TW); Yung-hao Chen, Taipei City (TW)

(21) Appl. No.: 17/586,794

(22) Filed: Jan. 28, 2022

(51) Int. Cl. H05K 7/20; G06F 1/20

(52) U.S. Cl. CPC H05K 7/20327; G06F 1/20; H05K 7/20309; H05K 7/20272

(57) ABSTRACT

An anti-tilt pressure mount assembly adapted for mounting an IC cooling system block having a bottom surface to an upper surface of a packaged IC, the packaged IC mounted to a circuit board, comprising a block housing having a central member and pair of outwardly facing L-shaped flange legs, clamping assembly having ready and clamped positions, and plurality of attachment members is provided. The plurality of attachment members secure the anti-tilt pressure mount assembly to the circuit board. When the clamping assembly is in a ready position, the IC cooling system block housed in the block housing is not clamped to the packaged IC. When the clamping assembly is in a clamped position, a compressive load is uniformly distributed to the upper surface of the packaged IC. The bottom surface of the IC cooling system block is only in thermal contact with the upper surface of the packaged IC.

### TECHNICAL FIELD

Example embodiments relate generally to the field of heat transfer and, more particularly, to anti-tilt IC cooling system block pressure mount assemblies.

### BACKGROUND

Surface-mount technology (SMT) allows electronic components (or surface-mount devices SMD) to be mounted directly to a surface of a printed circuit board (PCB) instead of being soldered to a wire lead. Thus, more components may be placed closer together, enabling higher circuit speeds and lighter weight devices, and lower resistance and inductance may be achieved at the connection, resulting in better high-frequency performance via mitigation of undesired RF signal effects. There are many types of SMDs, with each, able to be packaged in different forms. One type of SMD is the integrated circuit (IC), such as central processing units (CPUs), graphics processing units (GPUs), and System on a Chips (SoCs), and one type of packaging for ICs is ball grid array (BGA) packaging.

Ball grid array technology uses the under-side of the IC package for connection or pin-outs (array of solder balls), instead of using the edges of the IC package, allowing for higher pin density, lower thermal resistance, and lower inductance, resulting in more interconnection pins and increased performance at higher speeds. While BGA packaged SMDs transfer considerable heat away from the SMDs to a board than leaded devices, for ICs needing additional cooling, the ability to dissipate sufficient heat to maintain high device reliability through other pathways, such as an upper surface, is often required.

Several techniques have been developed for dissipating sufficient heat from an upper surface of BGA packaged ICs. One such technique incorporates heat spreaders directly into the BGA packages of the ICs via upper surface adherence, such as, integrated heat spreader (IHS) lids, enhancing thermal capabilities of the ICs. Thereafter, cooling systems, such as a top-mounted heat pipe-heat sink-cooling systems or liquid-cooling systems may be attached directly to the IHS. Another such technique attaches the cooling system directly to the upper surface of the BGA packages of the ICs without heat spreaders, such as with direct, bare, or naked die cooling. However, when assembling the cooling systems to the ICs, excessive forces due to standardized cooling system assemblies and height variation of the ICs during packaging or tilt forces when sequentially screwing or fastening the cooling systems to the ICs, results in a strain on the solder balls, potentially shearing the electrical and physical connection of the BGA packages of the ICs to the board.

While structures may be used to rigidly support the cooling systems in thermal contact with the upper surface of BGA packaged ICs, such as top plates, shim plates, frames, brackets, or the like, weight, size, number of parts, and complexity of the cooling system assembly increases and excessive forces due to standardized structures and height variation of the ICs during packaging or poor thermal contact between the cooling systems and upper surface of the ICs may occur. While thermal interface materials (TIMs) may be used to compensate for height variations, thicker TIMs decrease thermal performance. Additionally, reduction in cooling capacity due to thicker TIMs significantly impacts the IC performance and risk of component failure.

### SUMMARY

In an embodiment, an anti-tilt pressure mount assembly adapted for mounting an IC cooling system block having a bottom surface to an upper surface of a packaged integrated circuit, the packaged integrated circuit mounted to a socket, the socket mounted to a circuit board, comprising a block housing having a central member and pair of outwardly facing L-shaped flange legs, clamping assembly having ready and clamped positions, and plurality of attachment members is provided. The central member has a central aperture disposed through the central member, and a reinforcing assembly disposed near to the central aperture. The pair of outwardly facing L-shaped flange legs is connected and extended downwardly from respective opposing ends of the central member. Each pair of outwardly facing L-shaped flange legs has a connected end portion connected to the central member and a non-connected end portion opposite the connected end portion. Each non-connected end portion has a pair of side bores disposed through the non-connected end portion at respective opposing ends of the non-connected end portion. The clamping assembly is attached to the reinforcing assembly and has a ready position and a clamped position. The clamped position clamps the bottom surface of the IC cooling system block to the upper surface of the packaged integrated circuit. Each of the plurality of attachment members is received through each pair of side bores, securing the anti-tilt pressure mount assembly housing the IC cooling system block therein to the socket and circuit board. When the plurality of attachment members are secured to the socket and circuit board and the clamping assembly is in the ready position, the IC cooling system block is not clamped to the packaged integrated circuit. When the plurality of attachment members are secured to the socket and circuit board and the clamping assembly is moved to the clamped position, a compressive load is uniformly distributed to the upper surface of the packaged integrated circuit, whereby the bottom surface of the IC cooling system block is only in thermal contact with the upper surface of the packaged integrated circuit.

In certain embodiments, a dimension of the bottom surface of the IC cooling system block is larger than a dimension of the upper surface of the packaged integrated circuit, and no structure is assembled to the socket and circuit board to rigidly support the IC cooling system block in thermal contact with the upper surface of the packaged integrated circuit.

In certain embodiments, a dimension of an upper surface of the IC cooling system block is substantially similar to a dimension of the central member and a height of each of a pair of longitudinal side surfaces of the IC cooling block is smaller than a height of each connected end portion of the pair of outwardly facing L-shaped flange legs.

In the embodiments, when the clamping assembly is in the ready position, the bottom surface of the IC cooling system block is parallel with the upper surface of the packaged integrated circuit. In the embodiments, at least one of the clamping assembly or plurality of attachment members is adapted to adjust a clamping distance of the housed IC cooling system block or a height of the anti-tilt pressure mount assembly secured to the socket and circuit board, respectively, whereby a same compressive load is uniformly distributed to upper surfaces of different packaged integrated circuits having different thicknesses.

In the embodiments, at least one of the clamping assembly, plurality of attachment members, reinforcing assembly of the central member, or any combination of the foregoing is adapted to be friction loaded, whereby when the clamping assembly is in the clamped position, the clamping assembly is retained in place.

In certain embodiments, the clamping assembly comprises a clamp having a pair of cam wheels and a handle. Each pair of cam wheels has a pivot channel therethrough. The handle is connected and extended outwardly from the pair of cam wheels. In certain embodiments, the reinforcing assembly comprises a pair of attachment members and a head pin. Each pair of attachment members has an attachment bore therethrough. The pair of attachment members is connected and extended upwardly from respective opposing ends of the central aperture of the central member. The clamp is rotatably attached between the pair of attachment members via attachment of the head pin to each attachment bore and through each pivot channel. In certain embodiments, the plurality of attachment members comprise spring loaded screws. When the clamping assembly is in the ready position, a first distance from the pivot channel to a first edge of each of the pair of cam wheels is less than a second distance from the pivot channel to a second edge of each of the pair of cam wheels. When the clamping assembly is moved to the clamped position, the pair of cam wheels rotates through the central aperture and protrudes through a plane of the central member. The spring loaded screws of the plurality of attachment members distribute the uniform compressive load to the upper surface of the packaged integrated circuit via the pair of cam wheels. The spring loaded screws of the plurality of attachment members and an inner tilt angle of each of the pair of cam wheels of the clamping assembly, friction loads the clamp of the clamping assembly to retain the clamping assembly in place.

In certain embodiments, the clamping assembly comprises an adjustable member and a securing ring. The adjustable member has a knurled head and a cylindrical base having male threads thereon, a cylindrical groove, and a flat base. The cylindrical base is connected and extended outwardly from the knurled head, the flat base is disposed opposite the knurled head, and the cylindrical groove is disposed near to the flat base. The securing ring is removably attached to the cylindrical groove. In certain embodiments, the reinforcing assembly comprises a pre-bent plate having a central plate bore and a first securing end portion and second securing end portion opposite the first securing end portion. The first securing end portion and second securing end portion is fixedly attached to the central member longitudinally. The central plate bore is aligned with the central aperture of the central member. The cylindrical base is rotatably attached to the central aperture via female threads on the central aperture and protrudes through a plane of the central member and through the central plate bore. When the clamping assembly is in the clamped position, the clamping assembly distributes the uniform compressive load to the upper surface of the packaged integrated circuit and the pre-bent plate of the reinforcing assembly of the central member, friction loads the adjustable member of the clamping assembly to retain the clamping assembly in place.

In particular embodiments, the pre-bent plate further comprises a pair of central protruding members connected and extended downwardly from respective opposing sides of the central plate bore. The pre-bent plate is disposed on an inner surface of the central member. The securing ring is disposed flush against the pre-bent plate. When the clamping assembly is in the clamped position, the adjustable member of the clamping assembly distributes the uniform compressive load through the pair of central protruding members to the upper surface of the packaged integrated circuit and the pre-bent plate of the reinforcing assembly of the central member, friction loads the adjustable member of the clamping assembly to retain the clamping assembly in place.

In particular embodiments, the pre-bent plate is disposed on an upper surface of the central member. When the clamping assembly is in the clamped position, the adjustable member of the clamping assembly distributes the uniform compressive load through the member bottom surface to the upper surface of the packaged integrated circuit and the pre-bent plate of the reinforcing assembly of the central member, friction loads the adjustable member of the clamping assembly to retain the clamping assembly in place.

In certain embodiments, the clamping assembly comprises a clamp having a pair of central cam wheels. Each pair of central cam wheels has a central pivot channel therethrough and a central handle. The central handle is connected and extended outwardly from the pair of central cam wheels. In certain embodiments, the reinforcing assembly comprises a pre-bent plate, a central head pin, and a spring. The pre-bent plate has a pair of central attachment members, a first securing end portion, and a second securing end portion opposite the first securing end portion. Each pair of central attachment members has a central attachment bore therethrough and is connected and extended upwardly from a center of the pre-bent plate. The pre-bent plate is disposed on an inner surface of the central member. The first securing end portion and second securing end portion is fixedly attached to the central member longitudinally. The pair of central attachment members protrude through the central aperture. The clamp is rotatably attached between the pair of central attachment members via attachment of the central head pin to each central attachment bore and through each central pivot channel and the spring. When the clamping assembly is in the ready position, a first distance from the central pivot channel to a first edge of each of the pair of central cam wheels is greater than a second distance from the central pivot channel to a second edge of each of the pair of central cam wheels, wherein the pre-bent plate is lifted toward the central member. When the clamping assembly is moved to the clamped position, the pre-bent plate is lowered away from the central member. The clamp of the clamping assembly distributes the uniform compressive load through the pre-bent plate to the upper surface of the packaged integrated circuit and the spring of the reinforcing assembly, friction loads the adjustable member of the clamping assembly to retain the clamping assembly in place.

In certain embodiments, the IC cooling system block, is an IC cooling system block of an IC cooling system, and the IC cooling system is a heat pipe-heat sink-cooling system or a liquid-cooling system, and the IC cooling system block is a heat spreader block or a water block and pump unit, respectively.

In particular embodiments, the heat pipe-heat sink-cooling system further comprises a fin stack, and a plurality of heat pipes. Each plurality of heat pipes has working fluid therein and has an evaporator end portion, a condenser end portion opposite the evaporator end portion, and a transporting end portion between the evaporator end portion and condenser end portion. Each evaporator end portion is joined parallelly to the heat spreader block and each condenser end portion is joined parallelly to the fin stack. The bottom surface of the heat spreader block having the evaporator end portion joined thereto, is in thermal contact with the upper surface of the packaged integrated circuit, absorbing heat therefrom, vaporizing the working fluid in the evaporator end portion, transporting heated steam away to the condenser end portion joined to the fin stack, dissipating heat to the ambient, and condensing the vapor back to working fluid, and then returning the working fluid to the evaporator end portion through capillary action, repeating a continuous heat dissipation cyclical process.

In certain embodiments, the liquid-cooling system further comprises a radiator, a first conduit, a second conduit, and working fluid. The first conduit has a water block and pump unit first conduit end communicating with the water block and pump unit and a radiator first conduit end opposite the water block and pump unit first conduit end communicating with the radiator. The second conduit has a water block and pump unit second conduit end communicating with the water block and pump unit and a radiator second conduit end opposite the water block and pump second conduit end communicating with the radiator. The water block and pump unit, first and second conduits, and radiator form a closed-loop liquid-cooling system having working fluid therein. The bottom surface of the water block and pump unit, is in thermal contact with the upper surface of the packaged integrated circuit, transporting heat away therefrom, and then working fluid, circulating inside of the closed-loop liquid-cooling system, flows over the water block and pump unit, removing heat therefrom. In particular embodiments, the radiator has a fan mounted to a side of the radiator.

In the embodiments, the block housing and clamping assembly comprises at least one of a copper material, a nickel material, a stainless steel material, a titanium material, an aluminum material, or any combination of the foregoing, or a polymeric compound material, a ceramic material, or a metal and ceramic composite material.

### BRIEF DESCRIPTION OF THE DRAWINGS

Unless specified otherwise, the accompanying drawings illustrate aspects of the innovative subject matter described herein. Referring to the drawings, wherein like reference numerals indicate similar parts throughout the several views, several examples of anti-tilt IC cooling system block pressure mount assemblies incorporating aspects of the presently disclosed principles are illustrated by way of example, and not by way of limitation.

FIG. 1A depicts a representation of an embodiment of an anti-tilt IC cooling system block pressure mount assembly, secured to an IC cooling system block of an IC cooling system, mounted to a circuit board.

FIG. 1B depicts an exploded view of the embodiment of the anti-tilt IC cooling system block pressure mount assembly, secured to an IC cooling system block of an IC cooling system, mounted to a circuit board of FIG. 1A.

FIG. 1C depicts another representation of the embodiment of the anti-tilt IC cooling system block pressure mount assembly, clamping an IC cooling system block of an IC cooling system, mounted to a circuit board of FIG. 1A.

FIG. 1D depicts a cross-sectional view of the embodiment of the anti-tilt IC cooling system block pressure mount assembly, secured to an IC cooling system block of an IC cooling system, mounted to a circuit board of FIG. 1A.

FIG. 1E depicts a cross-sectional view of the embodiment of the anti-tilt IC cooling system block pressure mount assembly, clamping an IC cooling system block of an IC cooling system, mounted to a circuit board of FIG. 1C.

FIG. 1F depicts another cross-sectional view of the embodiment of the anti-tilt IC cooling system block pressure mount assembly, clamping an IC cooling system block of an IC cooling system, mounted to a circuit board of FIG. 1C.

FIG. 2A depicts a representation of the embodiment of an anti-tilt IC cooling system block pressure mount assembly of FIG. 1A.

FIG. 2B depicts another representation of the embodiment of the anti-tilt IC cooling system block pressure mount assembly of FIG. 2A.

FIG. 3 depicts a representation of an embodiment of an anti-tilt IC cooling system block pressure mount assembly, secured to another IC cooling system block of another IC cooling system, mounted to a circuit board.

FIG. 4 depicts a representation of an alternative embodiment of an anti-tilt IC cooling system block pressure mount assembly, clamping an IC cooling system block of an IC cooling system, mounted to a circuit board.

FIG. 5A depicts a representation of another alternative embodiment of an anti-tilt IC cooling system block pressure mount assembly, secured to an IC cooling system block of an IC cooling system, mounted to a circuit board.

FIG. 5B depicts an exploded view of the another alternative embodiment of the anti-tilt IC cooling system block pressure mount assembly, secured to an IC cooling system block of an IC cooling system, mounted to a circuit board of FIG. 5A.

FIG. 5C depicts another representation of the another alternative embodiment of the anti-tilt IC cooling system block pressure mount assembly, clamping an IC cooling system block of an IC cooling system, mounted to a circuit board of FIG. 5A.

FIG. 5D depicts a cross-sectional view of the another alternative embodiment of the anti-tilt IC cooling system block pressure mount assembly, secured to an IC cooling system block of an IC cooling system, mounted to a circuit board of FIG. 5A.

FIG. 5E depicts a cross-sectional view of the another alternative embodiment of the anti-tilt IC cooling system block pressure mount assembly, clamping an IC cooling system block of an IC cooling system, mounted to a circuit board of FIG. 5C.

FIG. 6A depicts a representation of the another alternative embodiment of the anti-tilt IC cooling system block pressure mount assembly of FIG. 5A.

FIG. 6B depicts another representation of the another alternative embodiment of the anti-tilt IC cooling system block pressure mount assembly of FIG. 6A.

FIG. 6C depicts yet another representation of the another alternative embodiment of the anti-tilt IC cooling system block pressure mount assembly of FIG. 6A.

FIG. 7 depicts a cross-sectional view of the embodiment of the another alternative block housing of the anti-tilt IC cooling system block pressure mount assembly of FIG. 6A.

FIG. 8 depicts a representation of an embodiment of an adjustable member of an anti-tilt IC cooling system block pressure mount assembly.

FIG. 9A depicts a representation of yet another alternative embodiment of an anti-tilt IC cooling system block pressure mount assembly, secured to an IC cooling system block of an IC cooling system, mounted to a circuit board.

FIG. 9B depicts an exploded view of the yet another alternative embodiment of the anti-tilt IC cooling system block pressure mount assembly, secured to an IC cooling system block of an IC cooling system, mounted to a circuit board of FIG. 9A.

FIG. 9C depicts another representation of the yet another alternative embodiment of the anti-tilt IC cooling system block pressure mount assembly, clamping an IC cooling system block of an IC cooling system, mounted to a circuit board of FIG. 9A.

FIG. 9D depicts a cross-sectional view of the yet another alternative embodiment of the anti-tilt IC cooling system block pressure mount assembly, secured to an IC cooling system block of an IC cooling system, mounted to a circuit board of FIG. 9A.

FIG. 9E depicts a cross-sectional view of the yet another alternative embodiment of the anti-tilt IC cooling system block pressure mount assembly, clamping an IC cooling system block of an IC cooling system, mounted to a circuit board of FIG. 5C.

FIG. 10A depicts a representation of the yet another alternative embodiment of the anti-tilt IC cooling system block pressure mount assembly of FIG. 9A.

FIG. 10B depicts another representation of the yet another alternative embodiment of the anti-tilt IC cooling system block pressure mount assembly of FIG. 9A.

FIG. 11A depicts a representation of an alternative embodiment of an anti-tilt IC cooling system block pressure mount assembly, secured to an IC cooling system block of an IC cooling system, mounted to a circuit board.

FIG. 11B depicts another representation of the alternative embodiment of an anti-tilt IC cooling system block pressure mount assembly, secured to an IC cooling system block of an IC cooling system, mounted to a circuit board of FIG. 11A.

FIG. 11C depicts an exploded view of the alternative embodiment of an anti-tilt IC cooling system block pressure mount assembly, secured to an IC cooling system block of an IC cooling system, mounted to a circuit board of FIG. 11A.

FIG. 11D depicts another representation of the alternative embodiment of the anti-tilt IC cooling system block pressure mount assembly, clamping an IC cooling system block of an IC cooling system, mounted to a circuit board of FIG. 11A.

FIG. 11E depicts a cross-sectional view of the alternative embodiment of the anti-tilt IC cooling system block pressure mount assembly, secured to an IC cooling system block of an IC cooling system, mounted to a circuit board of FIG. 11A.

FIG. 11F depicts a cross-sectional view of the alternative embodiment of the anti-tilt IC cooling system block pressure mount assembly, clamping an IC cooling system block of an IC cooling system, mounted to a circuit board of FIG. 11D.

FIG. 12A depicts a representation of the alternative embodiment of the anti-tilt IC cooling system block pressure mount assembly of FIG. 11A.

FIG. 12B depicts another representation of the alternative embodiment of the anti-tilt IC cooling system block pressure mount assembly of FIG. 12A.

FIG. 12C depicts yet another representation of the alternative embodiment of the anti-tilt IC cooling system block pressure mount assembly of FIG. 12A.

FIG. 13 depicts a cross-sectional view of an embodiment of the block housing of the anti-tilt IC cooling system block pressure mount assembly of FIG. 11A.

FIG. 14A depicts a representation of an alternative embodiment of an anti-tilt IC cooling system block pressure mount assembly, securing an IC cooling system block of an IC cooling system, mounted to a circuit board of FIG. 11A.

FIG. 14B depicts another representation of the alternative embodiment of an anti-tilt IC cooling system block pressure mount assembly, clamping an IC cooling system block of an IC cooling system, mounted to a circuit board of FIG. 14A.

FIG. 14C depicts a cross-sectional view of the alternative embodiment of an anti-tilt IC cooling system block pressure mount assembly, clamping an IC cooling system block of an IC cooling system, mounted to a circuit board of FIG. 14A.

### DETAILED DESCRIPTION

The following describes various principles related to anti-tilt pressure mount assemblies by way of reference to specific examples of block housings, clamping assemblies, and attachment members, including specific arrangements and examples of block housings, pump units, and flow guiding plates embodying innovative concepts. More particularly, but not exclusively, such innovative principles are described in relation to selected examples of clamps, spring loaded screws, and pre-bent plates and well-known functions or constructions are not described in detail for purposes of succinctness and clarity. Nonetheless, one or more of the disclosed principles can be incorporated in various other embodiments of clamping assemblies, attachment members, and pre-bent plates to achieve any of a variety of desired outcomes, characteristics, and/or performance criteria.

Thus, anti-tilt IC cooling system block pressure mount assemblies having attributes that are different from those specific examples discussed herein can embody one or more of the innovative principles, and can be used in applications not described herein in detail. Accordingly, embodiments of anti-tilt IC cooling system block pressure mount assemblies not described herein in detail also fall within the scope of this disclosure, as will be appreciated by those of ordinary skill in the relevant art following a review of this disclosure.

Example embodiments as disclosed herein are directed to anti-tilt pressure mount assemblies, wherein a block housing, housing a heat spreader block or a water block and pump unit therein, is secured to a socket and circuit board, whereby the heat spreader block or water block and pump unit is not clamped to a packaged integrated circuit having an upper surface and the heat spreader block or water block and pump unit is removable from or placeable within the anti-tilt pressure mount assembly. A clamping assembly clamps the bottom surface of the heat spreader block or water block and pump unit to the upper surface of the packaged integrated circuit, whereby a uniform compressive load is distributed to the upper surface of the packaged integrated circuit. No structure is assembled to the socket and circuit board to rigidly support the heat spreader block or water block and pump unit. The bottom surface of the heat spreader block or water block and pump unit is in thermal contact with the upper surface of the packaged integrated circuit, transporting heat away therefrom. At least one of the clamping assembly or plurality of attachment members is adapted to adjust a clamping distance of the housed heat spreader block or a water block and pump unit or a height of the anti-tilt pressure mount assembly secured to the socket and circuit board, respectively, whereby a same compressive load is uniformly distributed to upper surfaces of different packaged integrated circuits having different thicknesses. The clamping assembly is friction loaded to retain the clamping assembly in place.

The anti-tilt pressure mount assembly houses the heat spreader block or water block and pump unit of a heat pipe-heat sink-cooling system or a liquid-cooling system, respectively. The anti-tilt pressure mount assembly and heat pipe-heat sink-cooling system or liquid-cooling system may be configured within a chassis or as part of an electric or electronics system that includes heat generating devices to be cooled. The heat pipe-heat sink-cooling system comprises at least a heat spreader block, plurality of heat pipes having working fluid therein and an evaporator end portion and a condenser end portion, and a fin stack, and the liquid-cooling system comprises at least one liquid-based cooling loop, and both, may further comprise one or more fans. The one or more fans may be coupled to a back end of the fin stack or a radiator via fastener (e.g., bolts, screws, an adhesive material, etc.) at structural portions thereof, respectively, transporting air through the fin stack or radiator to an air plenum or to an outside of the chassis or electric or electronics system.

In an embodiment, anti-tilt pressure mount assembly adapted for mounting an IC cooling system block having a bottom surface to an upper surface of a packaged integrated circuit, the packaged integrated circuit mounted to a socket, the socket mounted to a circuit board, comprising a block housing having a central member and pair of outwardly facing L-shaped flange legs, clamping assembly having ready and clamped positions, and plurality of attachment members is provided. The central member has a central aperture disposed through the central member, and a reinforcing assembly disposed near to the central aperture. The pair of outwardly facing L-shaped flange legs is connected and extended downwardly from respective opposing ends of the central member. Each pair of outwardly facing L-shaped flange legs has a connected end portion connected to the central member and a non-connected end portion opposite the connected end portion. Each non-connected end portion has a pair of side bores disposed through the non-connected end portion at respective opposing ends of the non-connected end portion. The clamping assembly is attached to the reinforcing assembly and has a ready position and a clamped position. The clamped position clamps the bottom surface of the IC cooling system block to the upper surface of the packaged integrated circuit. Each of the plurality of attachment members is received through each pair of side bores, securing the anti-tilt pressure mount assembly housing the IC cooling system block therein to the socket and circuit board. When the plurality of attachment members are secured to the socket and circuit board and the clamping assembly is in the ready position, the IC cooling system block is not clamped to the packaged integrated circuit and the IC cooling system block is removable from or placeable within the anti-tilt pressure mount assembly. When the plurality of attachment members are secured to the socket and circuit board and the clamping assembly is moved to the clamped position, a compressive load is uniformly distributed to the upper surface of the packaged integrated circuit, whereby the bottom surface of the IC cooling system block is only in thermal contact with the upper surface of the packaged integrated circuit.

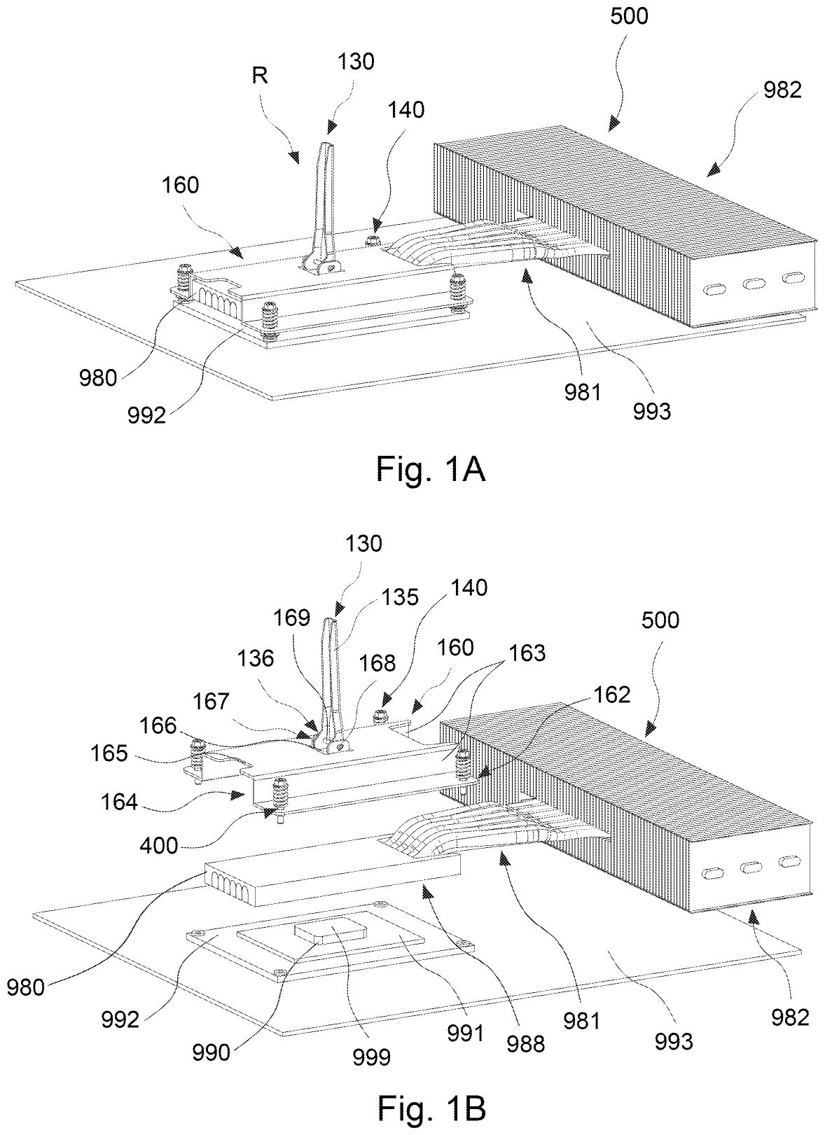

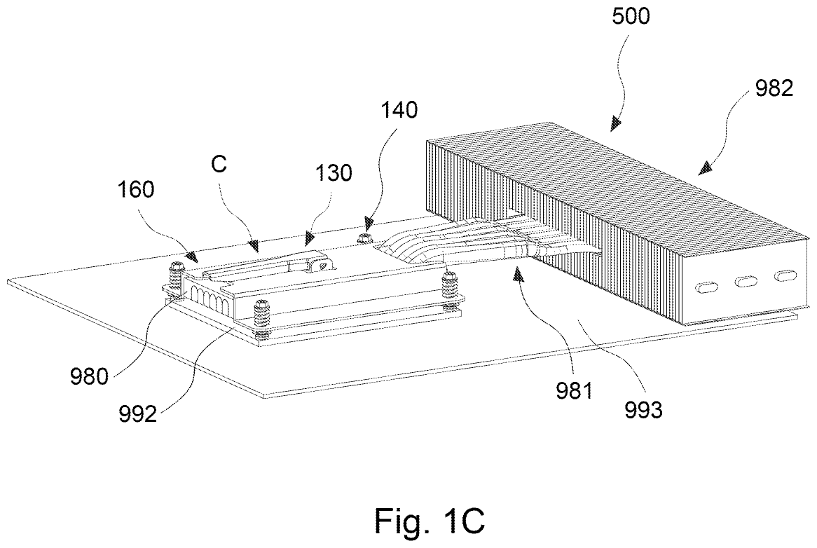

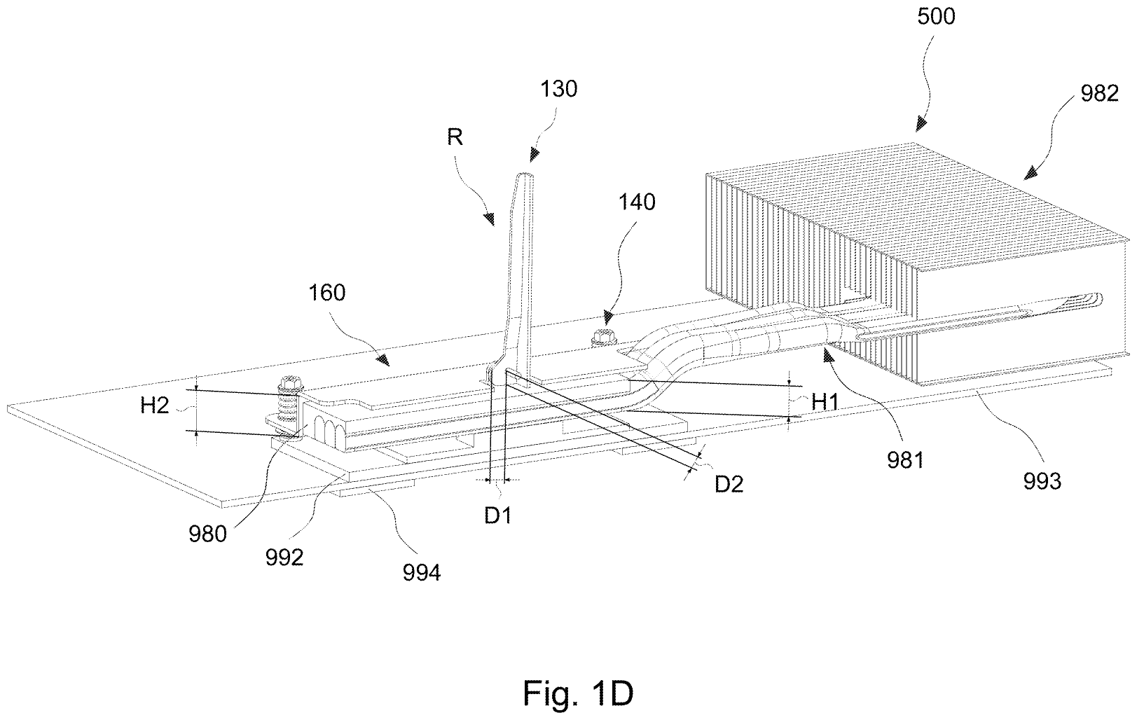

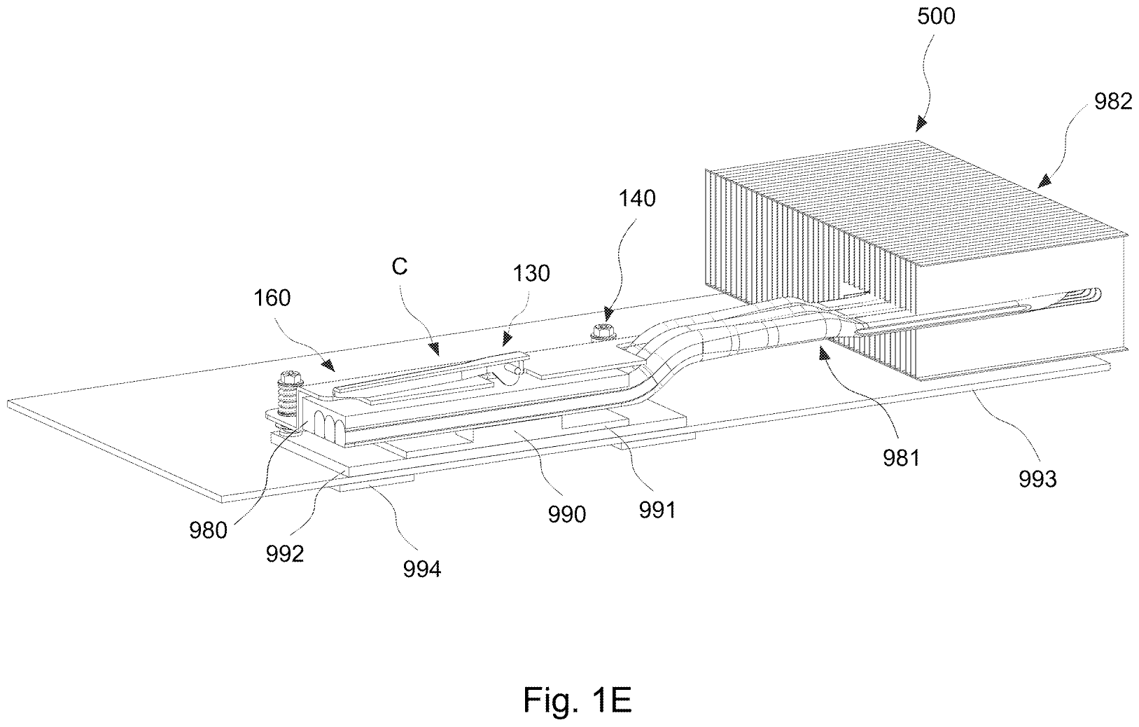

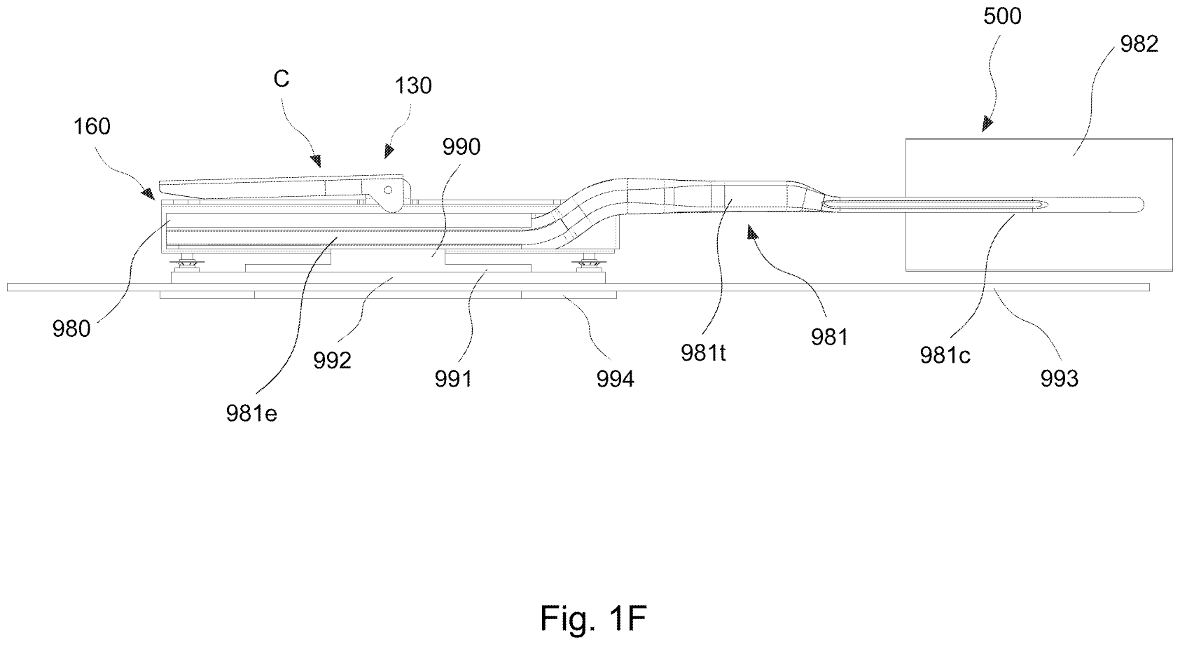

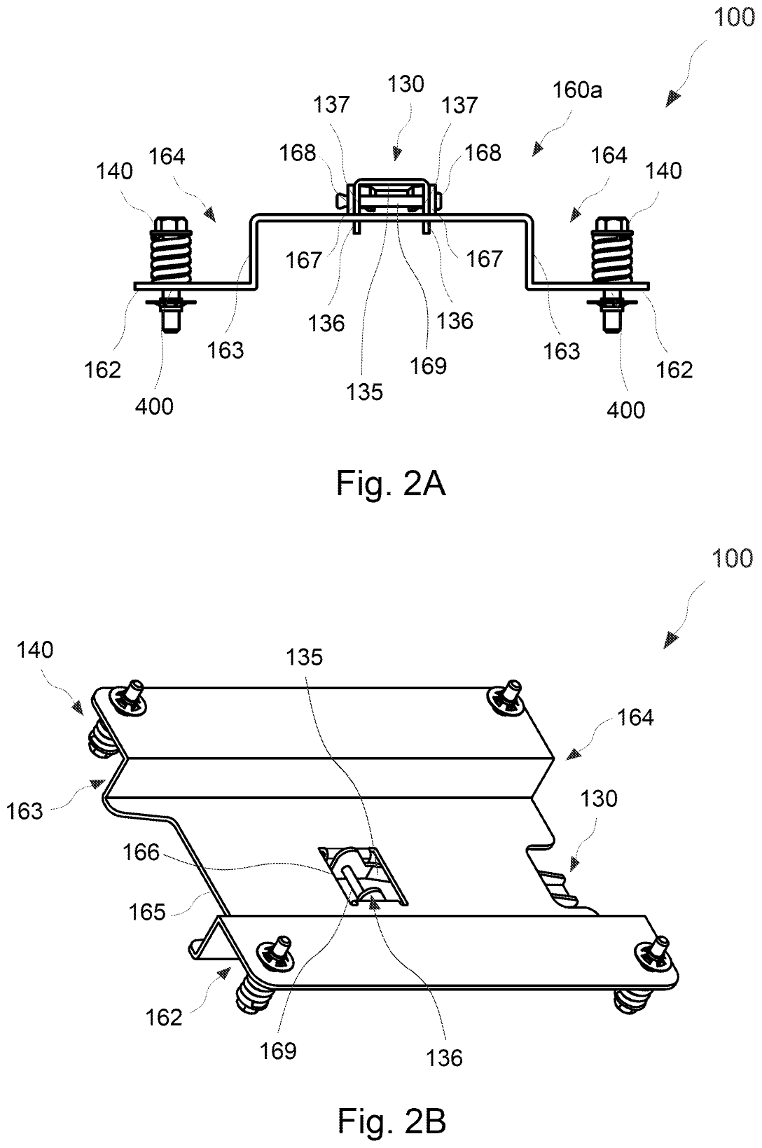

FIGS. 1A, 1B and 1D depict a representation and views of an embodiment of an anti-tilt IC cooling system block pressure mount assembly, secured to an IC cooling system block of an IC cooling system mounted to a circuit board. FIGS. 1C, 1E and 1F depict another representation and views of the embodiment of the anti-tilt IC cooling system block pressure mount assembly, clamping an IC cooling system block of an IC cooling system mounted to a circuit board of FIG. 1A. FIGS. 2A and 2B depict representations of the embodiment of an anti-tilt IC cooling system block pressure mount assembly of FIG. 1A. Referring to FIGS. 1A to 2B, in an embodiment, an anti-tilt pressure mount assembly 100 adapted for mounting an IC cooling system block 980 having a bottom surface 988 to an upper surface 999 of a packaged integrated circuit 990, the packaged integrated circuit 990 mounted to a substrate 991, the substrate 991 mounted to a socket 992, the socket 992 mounted to a circuit board 993, comprising a block housing 160 having a central member 165 and pair of outwardly facing L-shaped flange legs 164, clamping assembly having ready and clamped positions R, C, and plurality of attachment members 140 is provided. The central member 165 has a central aperture 166 disposed through the central member 165, and a reinforcing assembly disposed near to the central aperture 166. The pair of outwardly facing L-shaped flange legs 164 is connected and extended downwardly from respective opposing ends of the central member 165. Each pair of outwardly facing L-shaped flange legs 164 has a connected end portion 163 connected to the central member 165 and a non-connected end portion 162 opposite the connected end portion 163. Each non-connected end portion 162 has a pair of side bores 400 disposed through the non-connected end portion 162 at respective opposing ends of the non-connected end portion 162. The clamping assembly is attached to the reinforcing assembly and has a ready position R and a clamped position C. The clamped position C clamps the bottom surface 988 of the IC cooling system block 980 to the upper surface 999 of the packaged integrated circuit 990. Each of the plurality of attachment members 140 is received through each pair of side bores 400, securing the anti-tilt pressure mount assembly 100 housing the IC cooling system block 980 therein to the socket 992 and circuit board 993. When the plurality of attachment members 140 are secured to the socket 992 and circuit board 993 and the clamping assembly is in the ready position R, the IC cooling system block 980 is not clamped to the packaged integrated circuit 990 and the IC cooling system block 980 is removable from or placeable within the anti-tilt pressure mount assembly 100. When the plurality of attachment members 140 are secured to the socket 992 and circuit board 993 and the clamping assembly is moved to the clamped position C, a compressive load is uniformly distributed to the upper surface 999 of the packaged integrated circuit 990, whereby the bottom surface 988 of the IC cooling system block 980 is only in thermal contact with the upper surface 999 of the packaged integrated circuit 990.

In certain embodiments, the IC cooling system block 980, 920, is an IC cooling system block 980, 920 of an IC cooling system 500, 501a, 501b, 502a, 502b, 503 and the IC cooling system 500, 501a, 501b, 502a, 502b, 503 is a heat pipe-heat sink-cooling system 500, 501a, 501b, 502a, 502b, wherein the IC cooling system block 980, 920 is a heat spreader block 980. Referring again to FIGS. 1A to 2B, in particular embodiments, the heat pipe-heat sink-cooling system 500 further comprises a fin stack 982, and a plurality of heat pipes 981. Each plurality of heat pipes 981 has working fluid (not shown) therein and has an evaporator end portion 981e, a condenser end portion 981c opposite the evaporator end portion 981e, and a transporting end portion 981t between the evaporator end portion 981e and condenser end portion 981c. Each evaporator end portion 981e is joined parallelly to the heat spreader block 980 and each condenser end portion 981c is joined parallelly to the fin stack 982. The bottom surface 988 of the heat spreader block 980 having the evaporator end portion 981e joined thereto, is in thermal contact with the upper surface 999 of the packaged integrated circuit 990, absorbing heat therefrom, vaporizing the working fluid (not shown) in the evaporator end portion 981e, transporting heated steam away to the condenser end portion 981c joined to the fin stack 982, dissipating heat to the ambient, and condensing the vapor back to working fluid (not shown), and then returning the working fluid (not shown) to the evaporator end portion 981e through capillary action, repeating a continuous heat dissipation cyclical process.

Those of ordinary skill in the relevant art may readily appreciate that the IC cooling system and IC cooling system block may be any type of IC cooling system and IC cooling system block transporting heat away from a packaged integrated circuit and the embodiments are not limited thereto. Those of ordinary skill in the relevant art may readily appreciate that the IC cooling system and IC cooling system block, transporting heat away from a packaged integrated circuit, may be of any dimension and shape, and the embodiments are not limited thereto. As long as the IC cooling system block may be housed in the anti-tilt pressure mount assembly and secured to the socket 992 and circuit board 993 while not being clamped thereto, whereby when the clamping assembly is moved to the clamped position C, a compressive load is uniformly distributed to the upper surface 999 of the packaged integrated circuit 990.

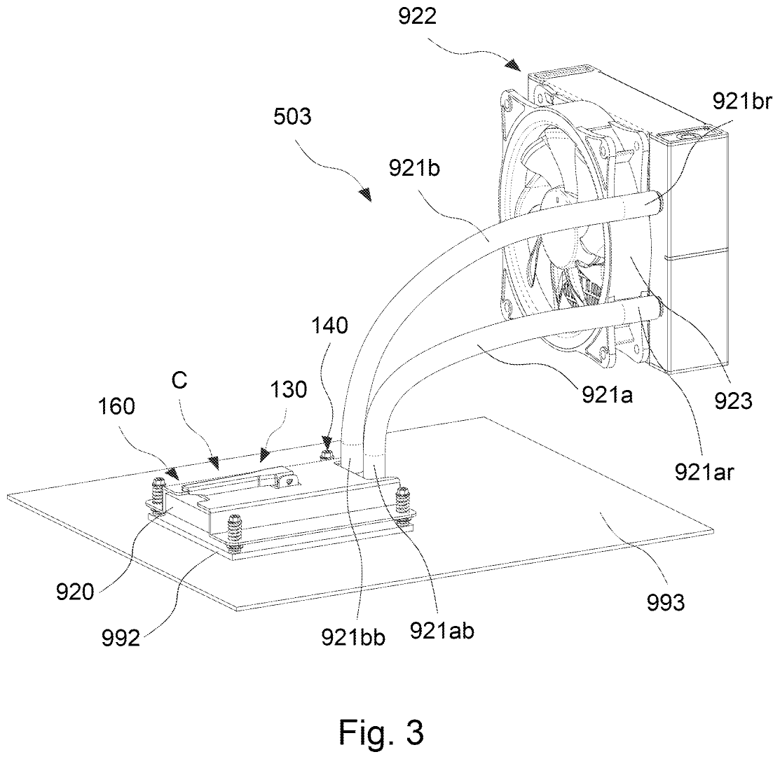

FIG. 3 depicts a representation of an embodiment of an anti-tilt IC cooling system block pressure mount assembly, secured to another IC cooling system block of another IC cooling system mounted to a circuit board. In certain embodiments, the IC cooling system block 980, 920, is an IC cooling system block 980, 920 of an IC cooling system 500, 501a, 501b, 502a, 502b, 503 and the IC cooling system 500, 501a, 501b, 502a, 502b, 503 is a liquid-cooling system 503, wherein the IC cooling system block 980, 920 is a water block and pump unit 920. Referring to FIG. 3 and referring to FIGS. 1A to 2B, in certain embodiments, the liquid-cooling system 503 further comprises a radiator 922, a first conduit 921a, a second conduit 921b, and working fluid (not shown). The first conduit 921a has a water block and pump unit first conduit end 921ap communicating with the water block and pump unit 920 and a radiator first conduit end 921r opposite the water block and pump unit first conduit end 921ap communicating with the radiator 922. The second conduit 921b has a water block and pump unit second conduit end 921bp communicating with the water block and pump unit 920 and a radiator second conduit end 921br opposite the water block and pump second conduit end 921bp communicating with the radiator 922. The water block and pump unit 920, first and second conduits 921a, 921b, and radiator 922 form a closed-loop liquid-cooling system 503 having working fluid (not shown) therein. The bottom surface (not shown) of the water block and pump unit (not shown), is in thermal contact with the upper surface (not shown) of the packaged integrated circuit (not shown), transporting heat away therefrom, and then working fluid (not shown), circulating inside of the closed-loop liquid-cooling system 503, flows over the water block and pump unit 920, removing heat therefrom. In particular embodiments, the radiator 922 has a fan 923 mounted to a side of the radiator 922.

In certain embodiments, a dimension of the bottom surface 988 of the IC cooling system block 980, 920 is larger than a dimension of the upper surface 999 of the packaged integrated circuit 990, and no structure is assembled to the socket 992 and circuit board 993 to rigidly support the IC cooling system block 980, 920 in thermal contact with the upper surface 999 of the packaged integrated circuit 990.

In certain embodiments, a dimension of an upper surface 999 of the IC cooling system block 980, 920 is substantially similar to a dimension of the central member 165 and a height H1 of each of a pair of longitudinal side surfaces of the IC cooling block is smaller than a height H2 of each connected end portion 163 of the pair of outwardly facing L-shaped flange legs 164.

In the embodiments, when the clamping assembly is in the ready position R, the bottom surface 988 of the IC cooling system block 980, 920 is parallel with the upper surface 999 of the packaged integrated circuit 990.

In particular embodiments, a plate 994 may be used on the bottom side of the circuit board 993 capturing the circuit board 993 between the plate 994 and the socket 992. The circuit board 993 may be a motherboard for a personal computer, a processor board, a memory board, a graphics board, or the like.

In the embodiments, at least one of the clamping assembly or plurality of attachment members 140, 141 is adapted to adjust a clamping distance of the housed IC cooling system block 980, 920 or a height of the anti-tilt pressure mount assembly 100, 201, 202, 300 secured to the socket 992 and circuit board 993 for example, via spacers, respectively, whereby a same compressive load is uniformly distributed to upper surfaces of different packaged integrated circuits having different thicknesses.

In the embodiments, at least one of the clamping assembly, plurality of attachment members 140, 141, reinforcing assembly of the central member 165, 265a, 265b, 365a, 365b, or any combination of the foregoing is adapted to be friction loaded, whereby when the clamping assembly is in the clamped position C, the clamping assembly is retained in place.

Referring again to FIGS. 1A to 2B, in certain embodiments, the clamping assembly comprises a clamp 130, 330 having a pair of cam wheels 136, 136 and a handle 135. Each pair of cam wheels 136, 136 has a pivot channel 137, 137 therethrough. The handle 135 is connected and extended outwardly from the pair of cam wheels 136, 136. In certain embodiments, the reinforcing assembly comprises a pair of attachment members 167, 167 and a head pin 169. Each pair of attachment members 167, 167 has an attachment bore 168, 168 therethrough. The pair of attachment members 167, 167 is connected and extended upwardly from respective opposing ends of the central aperture 166 of the central member 165. The clamp 130 is rotatably attached between the pair of attachment members 167, 167 via attachment of the head pin 169 to each attachment bore 168, 168 and through each pivot channel 137, 137. In certain embodiments, the plurality of attachment members 140 comprise spring loaded screws. When the clamping assembly is in the ready position R, a first distance D1 from the pivot channel 137, 137 to a first edge of each of the pair of cam wheels 136, 136 is less than a second distance D2 from the pivot channel 137, 137 to a second edge of each of the pair of cam wheels 136, 136. When the clamping assembly is moved to the clamped position C, the pair of cam wheels 136, 136 rotates through the central aperture 166 and protrudes through a plane of the central member 165. The spring-loaded screws of the plurality of attachment members 140 distribute the uniform compressive load to the upper surface 999 of the packaged integrated circuit 990 via the pair of cam wheels 136, 136. The spring-loaded screws of the plurality of attachment members 140 and an inner tilt angle of each of the pair of cam wheels 136, 136 of the clamping assembly in relation to the upper surface 999 of the packaged integrated circuit 990, bias and force the clamping assembly against an upper surface of the central member 165, friction loading the clamp 130 of the clamping assembly to retain the clamping assembly in place.

In certain embodiments the plurality of attachment members 140 comprise spring loaded screws. However, those of ordinary skill in the relevant art may readily appreciate that the plurality of attachment members 141 may be any type of attachment member, for example, a screw, and the embodiments are not limited thereto. As long as the IC cooling system block may be secured to the socket 992 and circuit board 993 while not being clamped thereto, whereby when the clamping assembly is moved to the clamped position C, a compressive load is uniformly distributed to the upper surface 999 of the packaged integrated circuit 990. Additionally, as long as at least one of the clamping assembly or plurality of attachment members 140, 141 may be adapted to adjust a clamping distance of the housed IC cooling system block 980, 920 or a height of the anti-tilt pressure mount assembly 100, 201, 202, 300 secured to the socket 992 and circuit board 993 for example, via spacers, respectively, whereby a same compressive load is uniformly distributed to upper surfaces of different packaged integrated circuits having different thicknesses.

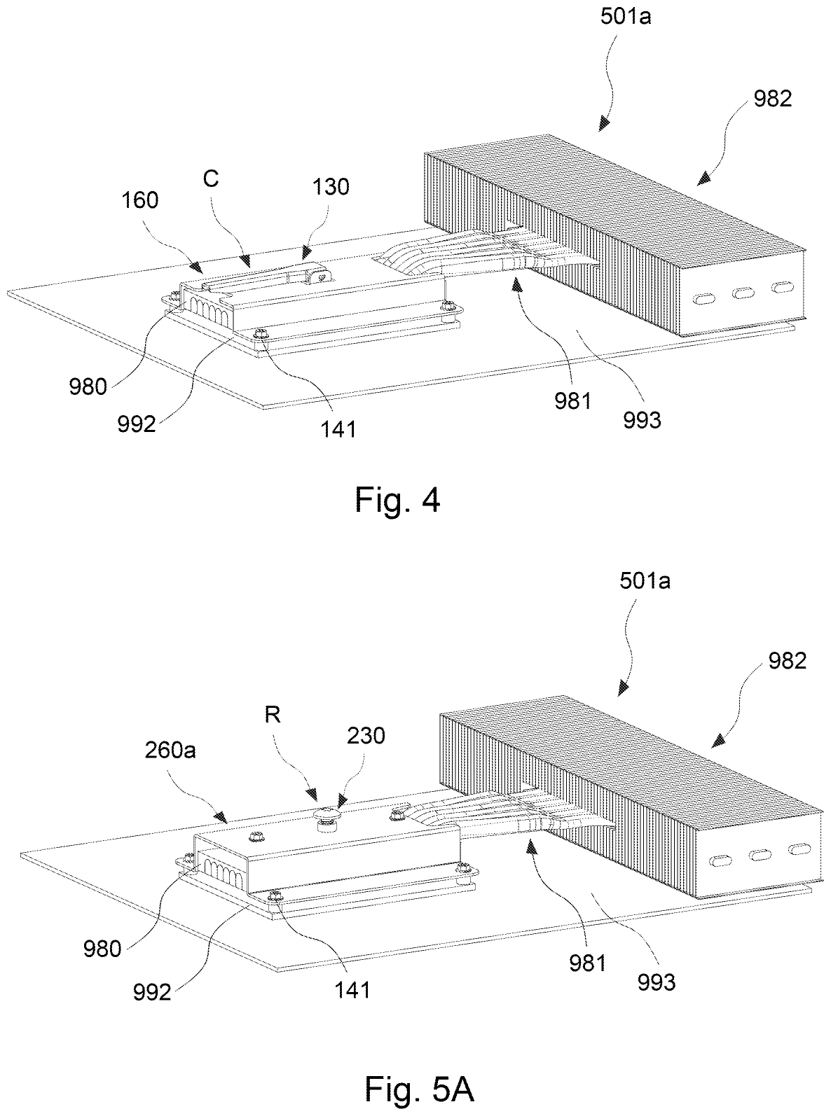

FIG. 4 depicts a representation of an alternative embodiment of an anti-tilt IC cooling system block pressure mount assembly, clamping an IC cooling system block of an IC cooling system mounted to a circuit board. Referring to FIG. 4 and referring to FIGS. 1A to 2B, the plurality of attachment members 141 comprise screws and like elements and features of the anti-tilt IC cooling system block pressure mount assembly 100 adapted for mounting an IC cooling system block 980, 920 having a bottom surface 988, (not shown) to an upper surface 999 of a packaged integrated circuit 990, the packaged integrated circuit 990 mounted to a substrate 991, the substrate 991 mounted to a socket 992, the socket 992 mounted to a circuit board 993, comprising the block housing 160 and clamping assembly is as described previously in the embodiments of the anti-tilt IC cooling system block pressure mount assembly 100, as an example and not to be limiting, such as the clamp 130 and the central member 165 and pair of outwardly facing L-shaped flange legs 164, and for sake of brevity, will not be repeated hereafter.

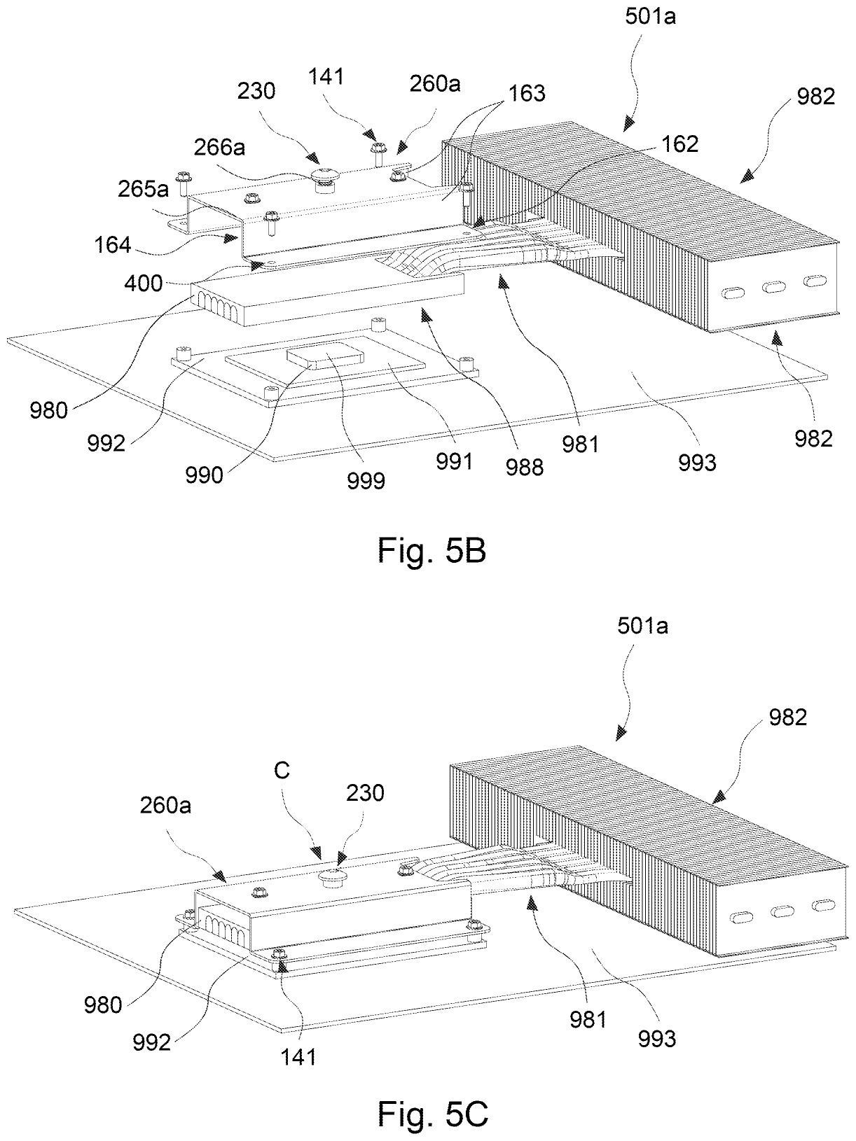

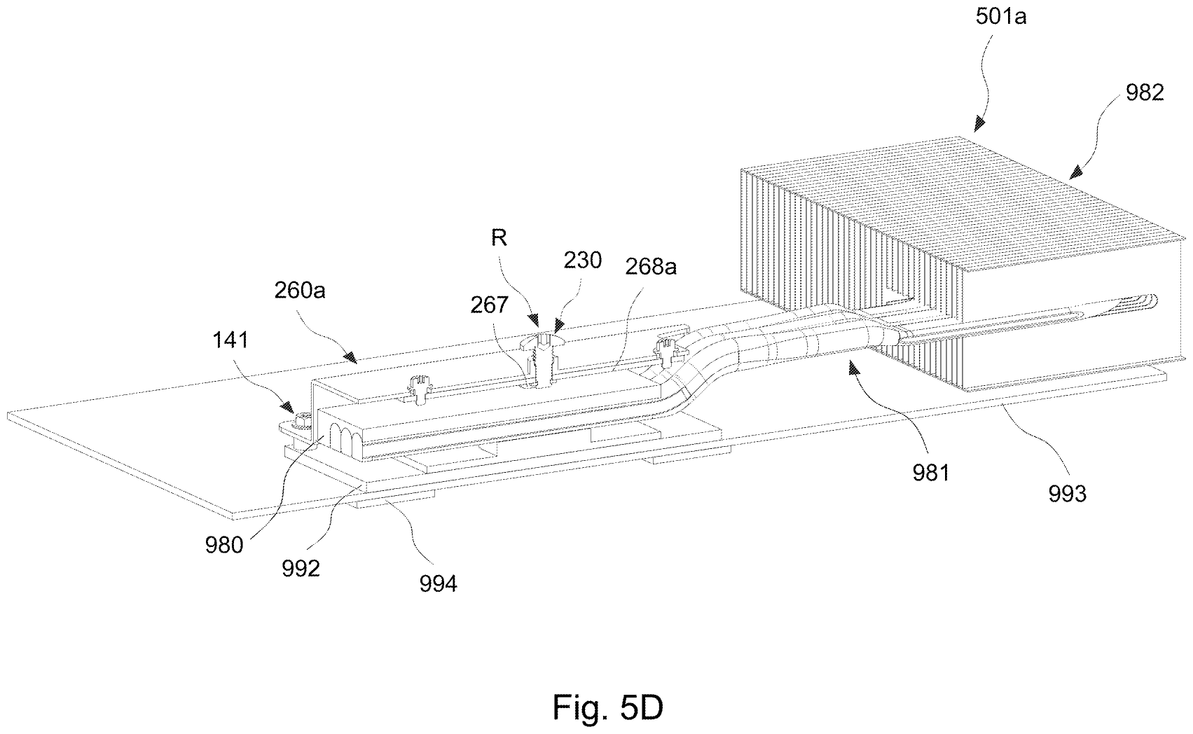

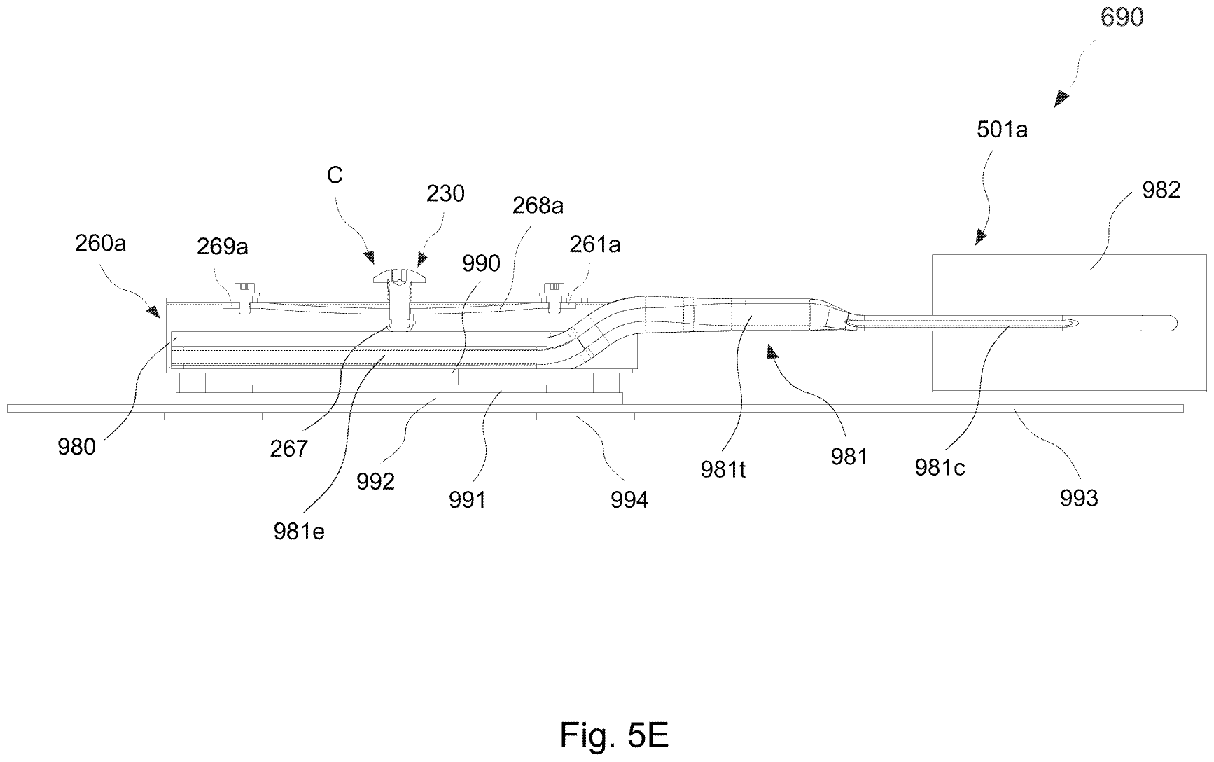

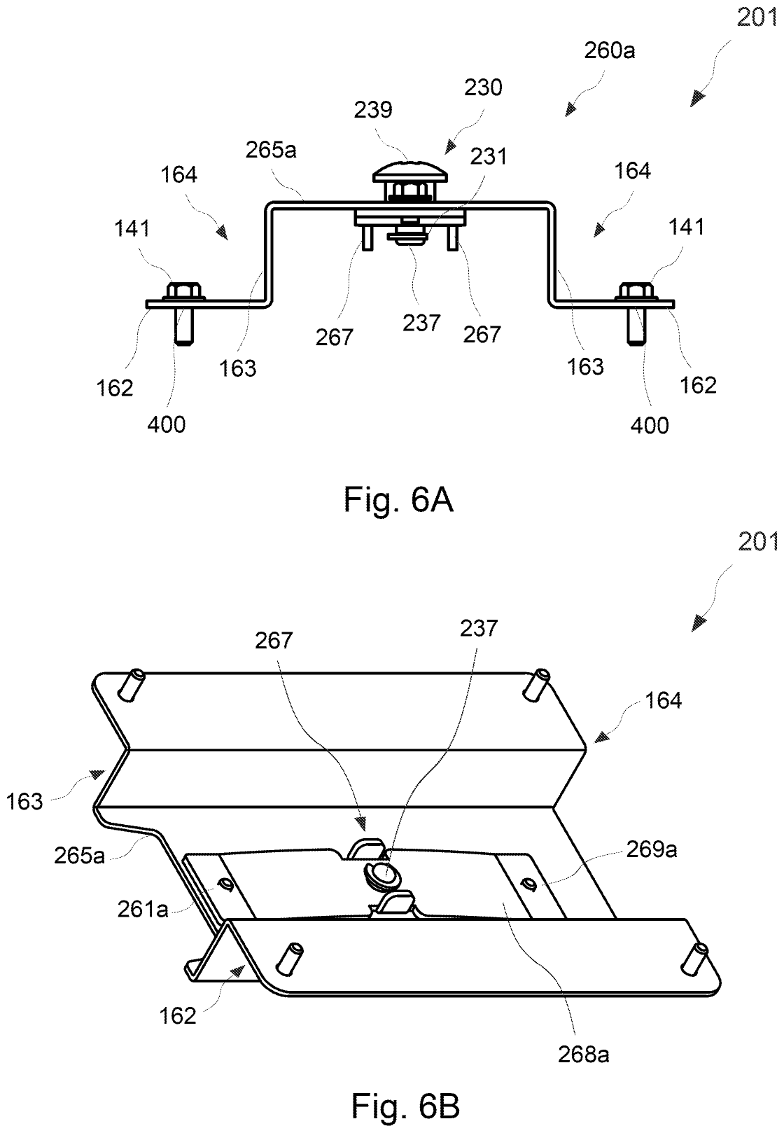

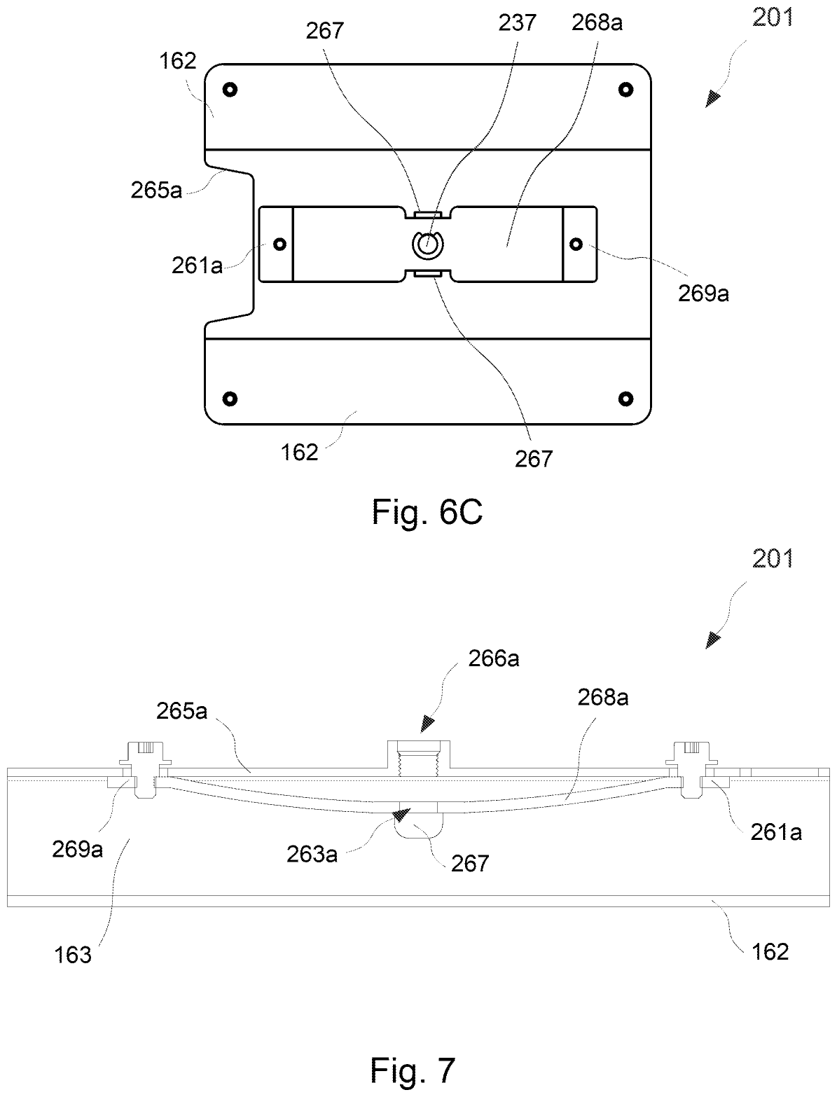

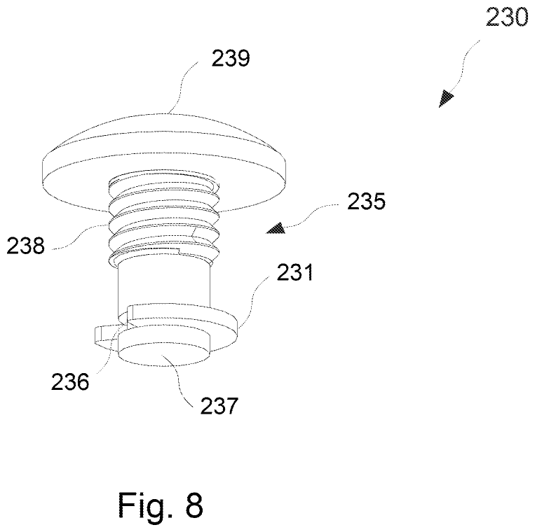

FIGS. 5A, 5B and 5D depict a representation and views of another alternative embodiment of an anti-tilt IC cooling system block pressure mount assembly, secured to an IC cooling system block of an IC cooling system mounted to a circuit board. FIGS. 5C and 5E depict another representation and view of the another alternative embodiment of the anti-tilt IC cooling system block pressure mount assembly, clamping an IC cooling system block of an IC cooling system mounted to a circuit board of FIG. 5A. FIGS. 6A to 7 depict representations and a view of the another alternative embodiment of the anti-tilt IC cooling system block pressure mount assembly of FIG. 5A. FIG. 8 depicts a representation of an embodiment of an adjustable member of an anti-tilt IC cooling system block pressure mount assembly. Referring to FIGS. 5A to 8, in certain embodiments, the clamping assembly comprises an adjustable member 230 and a securing ring 231. The adjustable member 230 has a knurled head 239 and a cylindrical base 235 having male threads 238 thereon, a cylindrical groove 236, and a flat base 237. The cylindrical base 235 is connected and extended outwardly from the knurled head 239, the flat base 237 is disposed opposite the knurled head 239, and the cylindrical groove 236 is disposed near to the flat base 237. The securing ring 231 is removably attached to the cylindrical groove 236. In certain embodiments, the reinforcing assembly comprises a pre-bent plate 268a having a central plate bore 263a and a first securing end portion 261a and second securing end portion 269a opposite the first securing end portion 261a. The first securing end portion 261a and second securing end portion 269a is fixedly attached to the central member 265a longitudinally. The central plate bore 263a is aligned and has a same size and shape with the central aperture 266a of the central member 265a. The cylindrical base 235 is rotatably attached to the central aperture 266a via female threads on the central aperture 266a and protrudes through a plane of the central member 265a and through the central plate bore 263a. When the clamping assembly is in the clamped position C, the clamping assembly distributes the uniform compressive load to the upper surface 999 of the packaged integrated circuit 990 and the pre-bent plate 268a of the reinforcing assembly of the central member 265a, friction loads the adjustable member 230 of the clamping assembly to retain the clamping assembly in place.

In the embodiments, the male threads 238 have a continuous single thread helical pattern and the female threads have a continuous single thread helical pattern. However, the female threads may also be interrupted segments in a standard helical pattern or other types of interrupted thread configurations and the embodiments are not limited thereto.

In particular embodiments, the pre-bent plate 268a further comprises a pair of central protruding members 267, 267 connected and extended downwardly from respective opposing sides of the central plate bore 263a. The pre-bent plate 268a is disposed on an inner surface of the central member 265a. The securing ring 231 is disposed flush against the pre-bent plate 268a. When the clamping assembly is moved to the clamped position C, the adjustable member 230 moves downward to the upper surface 999 of the packaged integrated circuit 990 and the pre-bent plate 268a, via downward tensioning against the securing ring 231, moves downward toward the upper surface 999 of the packaged integrated circuit 990. When the clamping assembly is in the clamped position C, the adjustable member 230 of the clamping assembly distributes the uniform compressive load through the pair of central protruding members 267, 267 to the upper surface 999 of the packaged integrated circuit 990 and the pre-bent plate 268a of the reinforcing assembly of the central member 265a, friction loads the adjustable member 230 of the clamping assembly to retain the clamping assembly in place.

Like elements and features of the anti-tilt IC cooling system block pressure mount assembly 201 adapted for mounting an IC cooling system block 980 having a bottom surface 988 to an upper surface 999 of a packaged integrated circuit 990, the packaged integrated circuit 990 mounted to a substrate 991, the substrate 991 mounted to a socket 992, the socket 992 mounted to a circuit board 993, comprising the block housing 160 and plurality of attachment members 140 is as described previously in the embodiments of the anti-tilt IC cooling system block pressure mount assembly 100, as an example and not to be limiting, such as the pair of outwardly facing L-shaped flange legs 164, and for sake of brevity, will not be repeated hereafter.

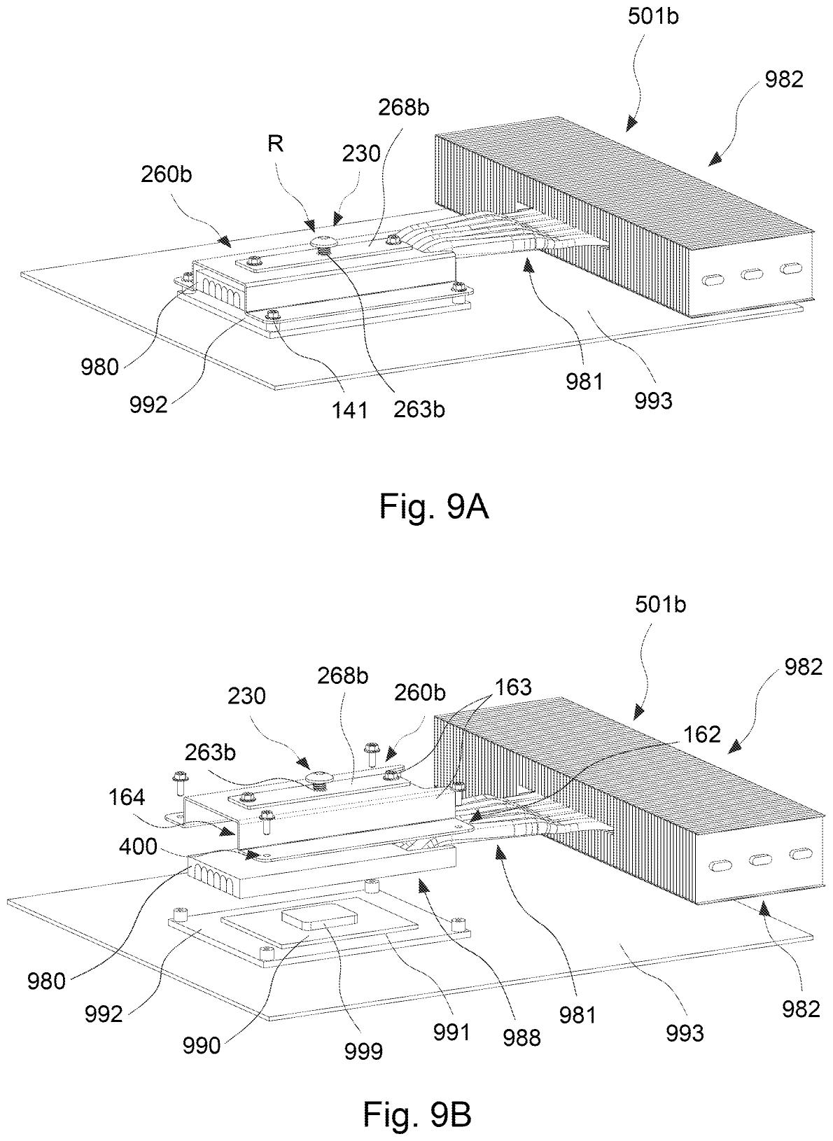

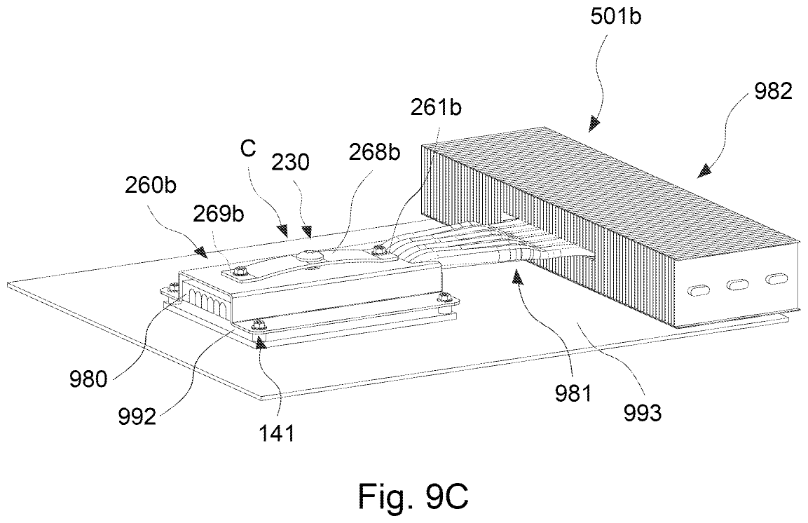

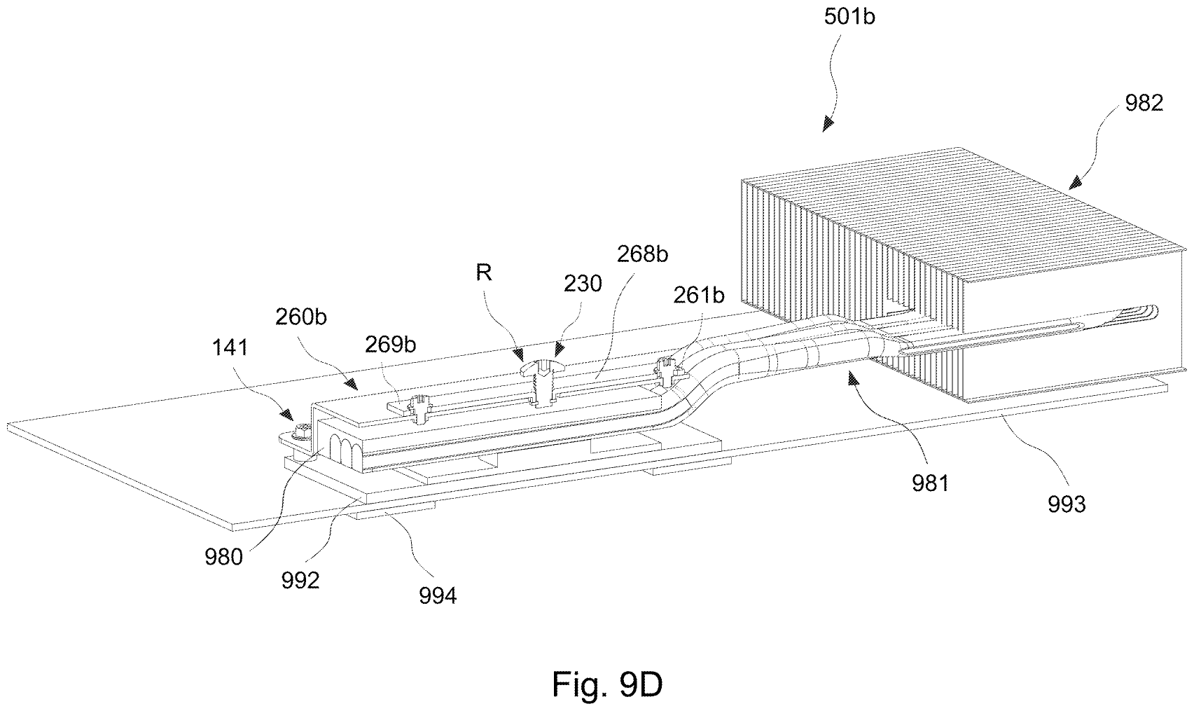

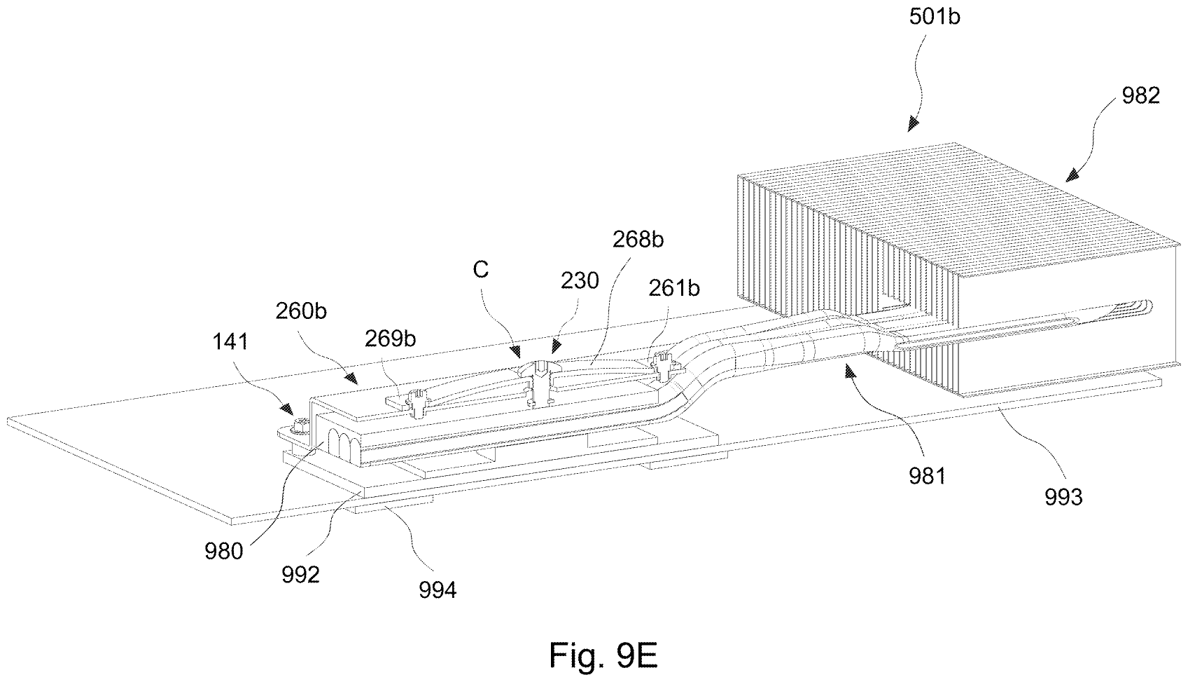

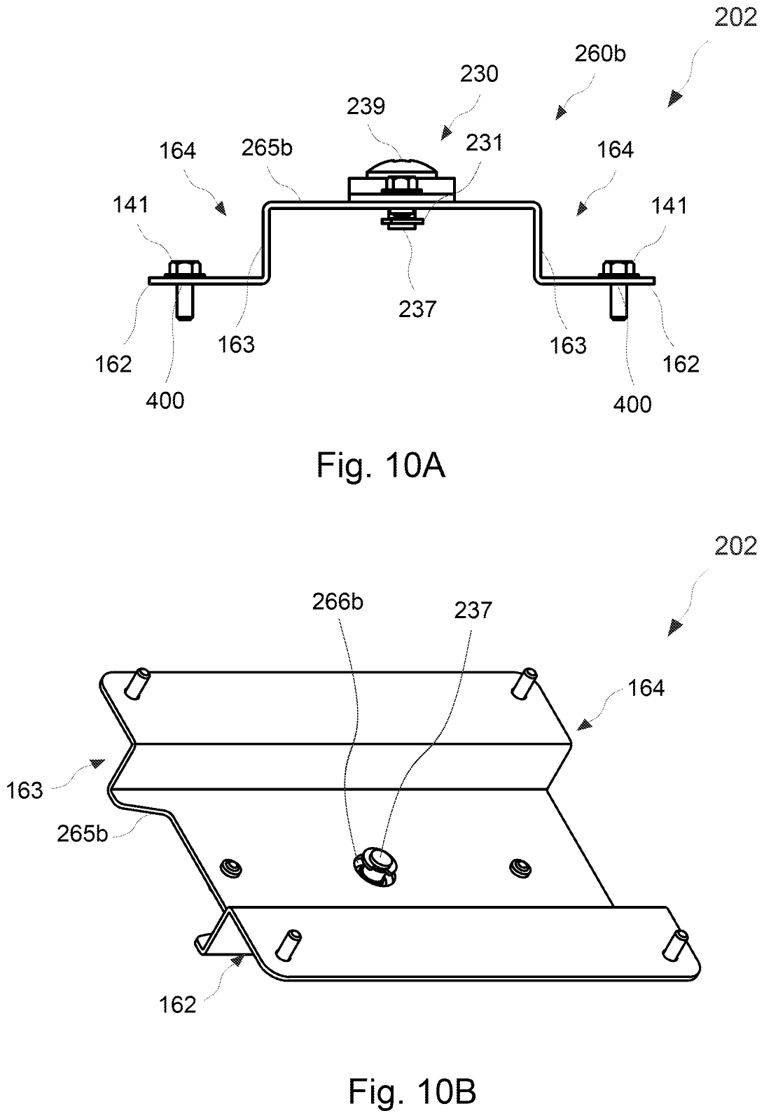

In particular embodiments, the pre-bent plate 268a is disposed on an inner surface of the central member 265a. However, the embodiments are not limited thereto. FIGS. 9A, 9B and 9D depict a representation and views of yet another alternative embodiment of an anti-tilt IC cooling system block pressure mount assembly, secured to an IC cooling system block of an IC cooling system mounted to a circuit board. FIGS. 9C and 9E depict another representation and view of the yet another alternative embodiment of the anti-tilt IC cooling system block pressure mount assembly, clamping an IC cooling system block of an IC cooling system mounted to a circuit board of FIG. 9A. FIGS. 10A and 10B depict representations of the yet another alternative embodiment of the anti-tilt IC cooling system block pressure mount assembly of FIG. 9A. Referring to FIGS. 9A to 10B, in particular embodiments, the pre-bent plate 268b is disposed on an upper surface of the central member 265b. Referring to FIGS. 9A to 10B, and referring 5A to 8, in certain embodiments, the clamping assembly comprises the adjustable member 230 and the securing ring 231. The adjustable member 230 has the knurled head 239 and the cylindrical base 235 having male threads 238 thereon, has the cylindrical groove 236, and flat base 237. The cylindrical base 235 is connected and extended outwardly from the knurled head 239, the flat base 237 is disposed opposite the knurled head 239, and the cylindrical groove 236 is disposed near to the flat base 237. The securing ring 231 is removably attached to the cylindrical groove 236. In particular embodiments, the reinforcing assembly comprises a pre-bent plate 268b having a central plate bore 263b and a first securing end portion 261b and second securing end portion 269b opposite the first securing end portion 261b. The pre-bent plate 268b is disposed on an upper surface of the central member 265b. The first securing end portion 261b and second securing end portion 269b is fixedly attached to the central member 265b longitudinally. The central plate bore 263b is aligned and has a same size and shape with the central aperture 266b of the central member 265b. The cylindrical base 235 is rotatably attached to the central plate bore 263b and the central aperture 266b via female threads on the central plate bore 263b and central aperture 266b, respectively, and protrudes through planes of the pre-bent plate 268b and the central member 265b. When the clamping assembly is moved to the clamped position C, the adjustable member 230 moves downward to the upper surface 999 of the packaged integrated circuit 990 and the pre-bent plate 268b, via the female threads on the central plate bore 263b, moves upward to an inner surface of the knurled head 239. When the clamping assembly is moved to the clamped position C, the adjustable member 230 moves downward to the upper surface 999 of the packaged integrated circuit 990 and the pre-bent plate 268b, via the female threads on the central plate bore 263b, moves upward to an inner surface of the knurled head 239. When the clamping assembly is in the clamped position C, the adjustable member 230 of the clamping assembly distributes the uniform compressive load through the flat base 237 to the upper surface 999 of the packaged integrated circuit 990 and the pre-bent plate 268b of the reinforcing assembly of the central member 265b, friction loads the adjustable member 230 of the clamping assembly to retain the clamping assembly in place.

Like elements and features of the anti-tilt IC cooling system block pressure mount assembly 202 adapted for mounting an IC cooling system block 980 having a bottom surface 988 to an upper surface 999 of a packaged integrated circuit 990, the packaged integrated circuit 990 mounted to a substrate 991, the substrate 991 mounted to a socket 992, the socket 992 mounted to a circuit board 993, comprising the block housing 160 and plurality of attachment members 141 is as described previously in the embodiments of the anti-tilt IC cooling system block pressure mount assembly 100, as an example and not to be limiting, such as the pair of outwardly facing L-shaped flange legs 164, and for sake of brevity, will not be repeated hereafter.

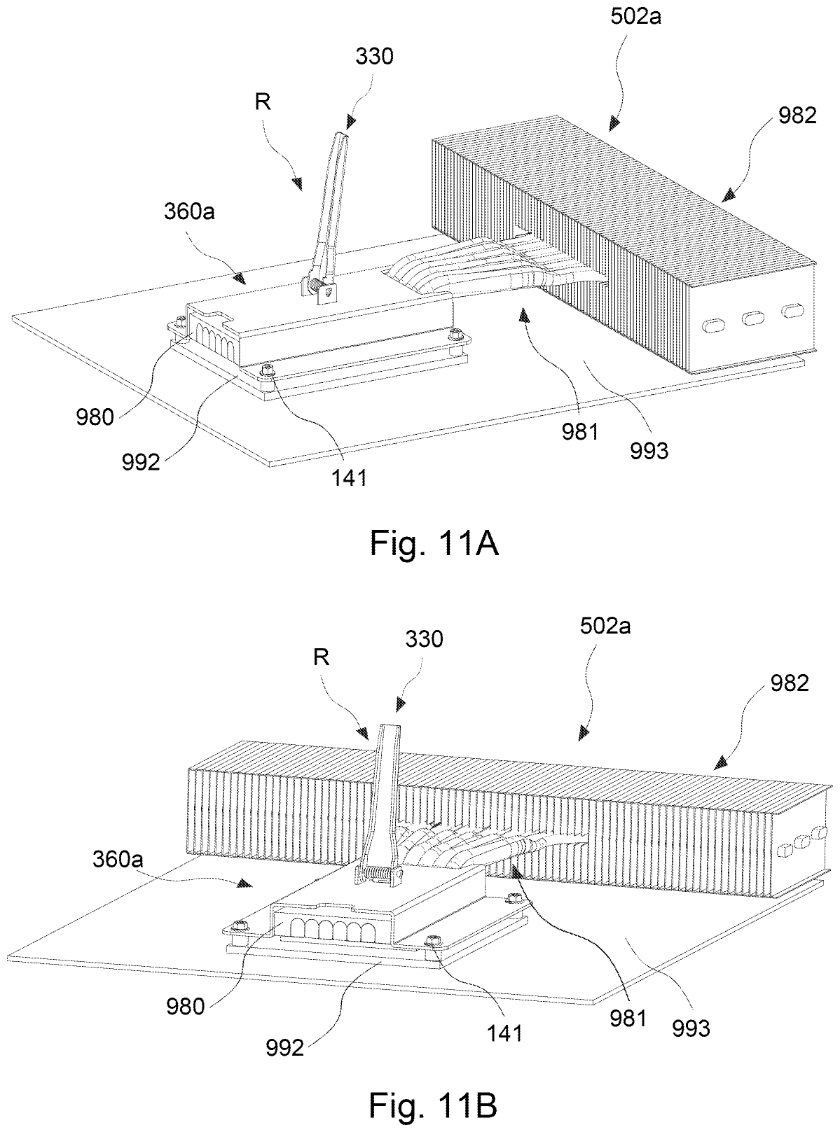

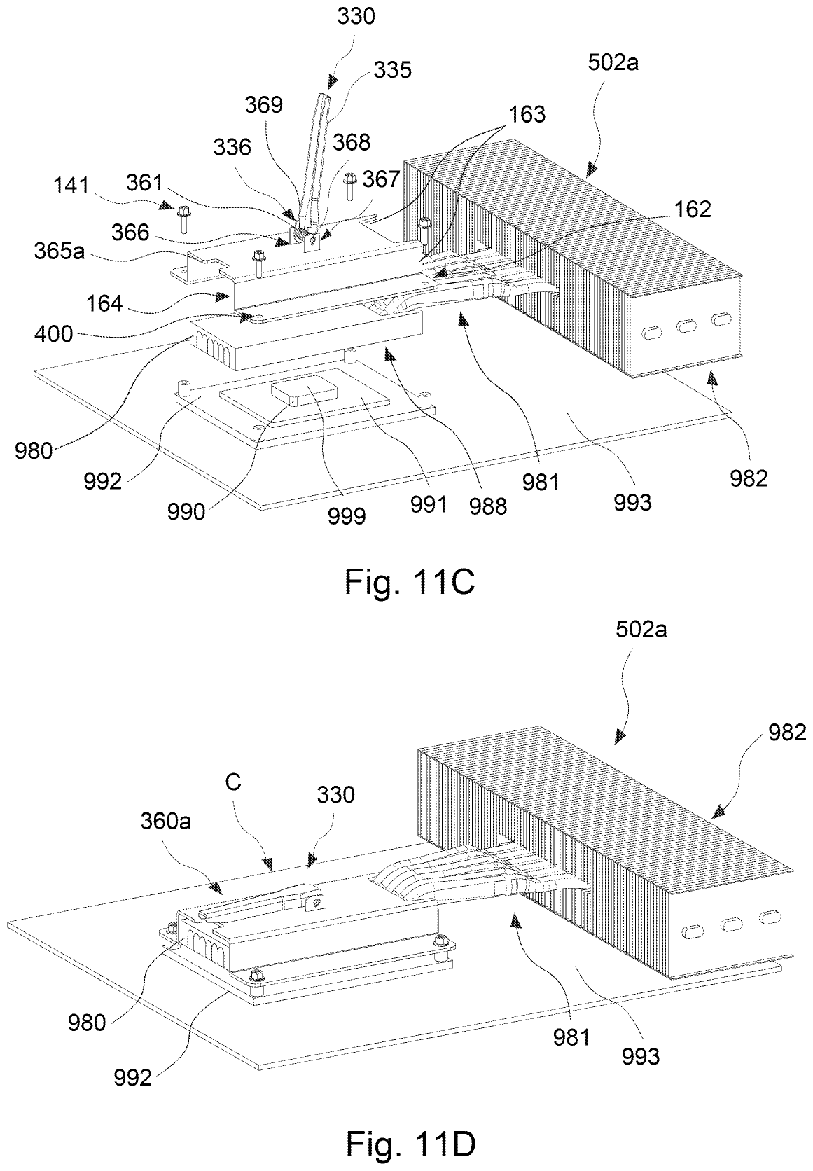

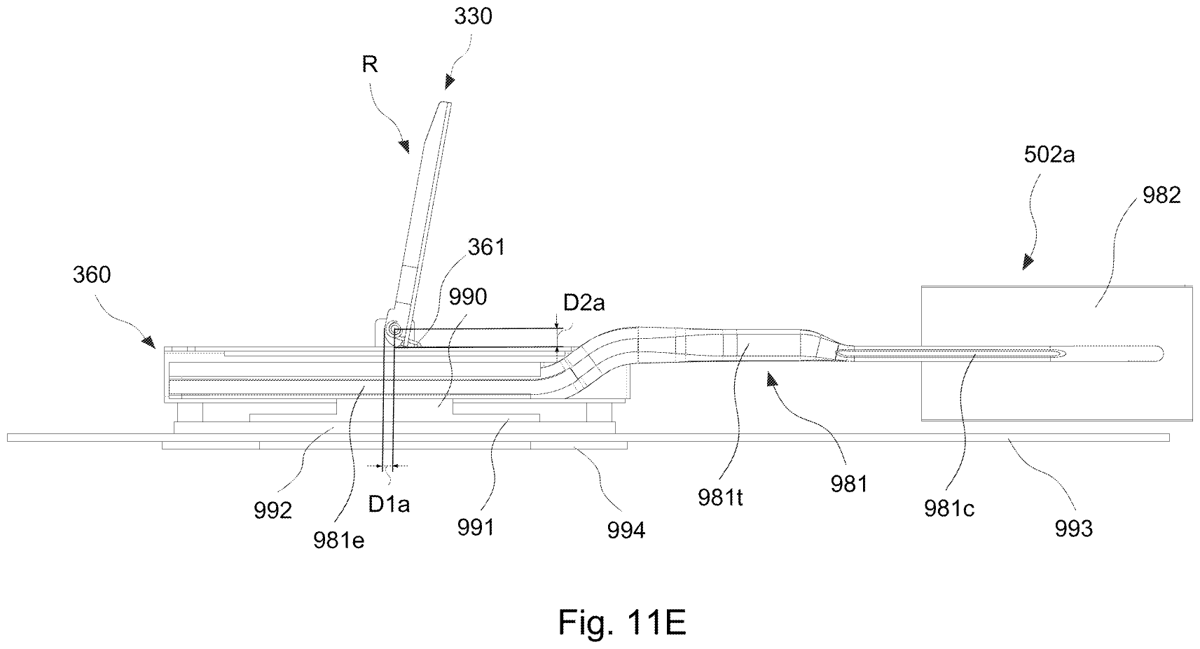

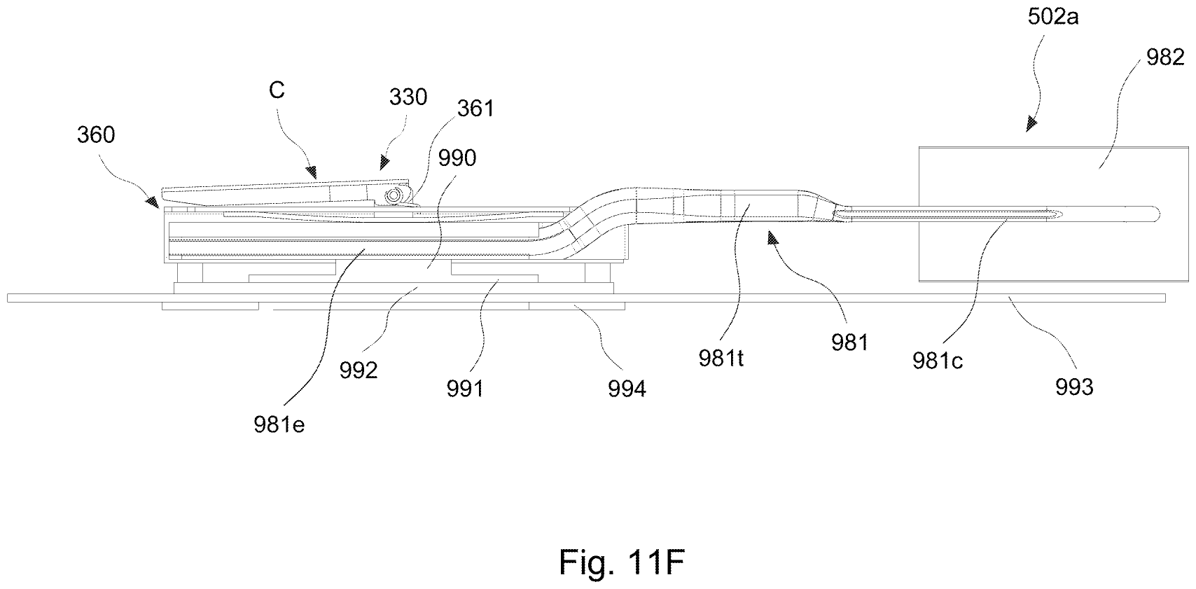

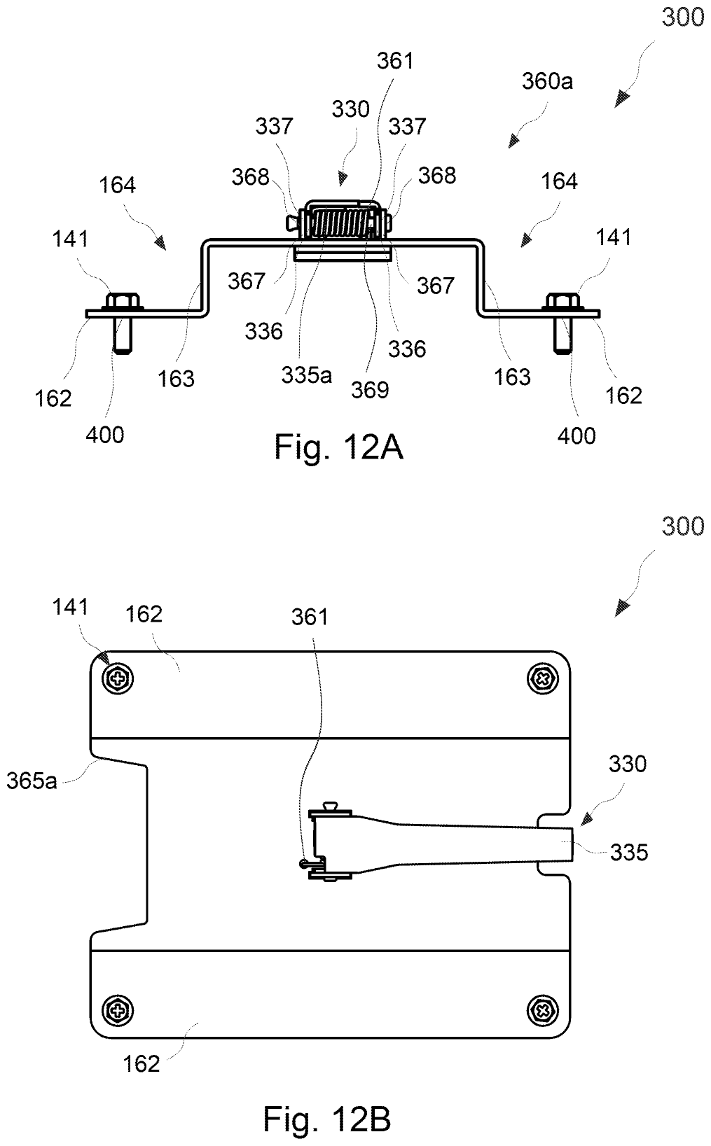

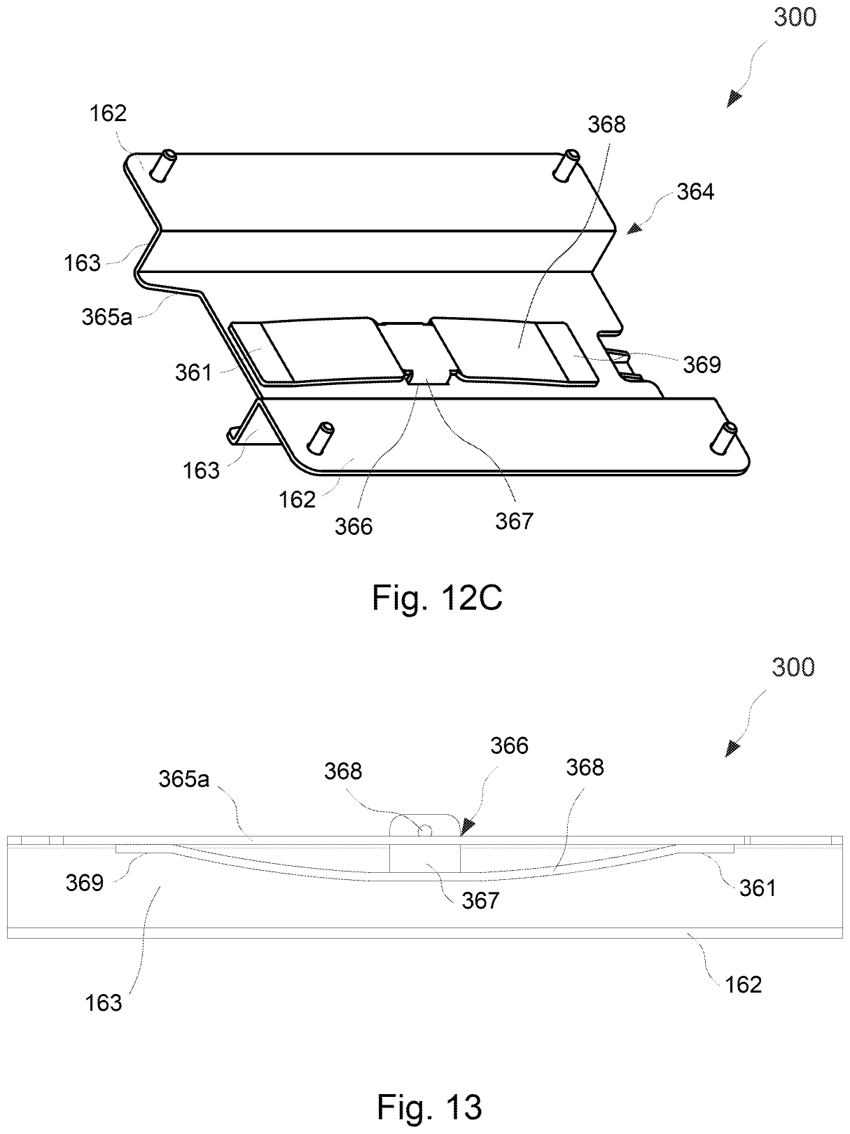

FIGS. 11A, 11B, 11C and 11E depict representations and views of an alternative embodiment of an anti-tilt IC cooling system block pressure mount assembly, secured to an IC cooling system block of an IC cooling system mounted to a circuit board. FIGS. 11D and 11F depict another representation and view of the alternative embodiment of the anti-tilt IC cooling system block pressure mount assembly, clamping an IC cooling system block of an IC cooling system mounted to a circuit board of FIG. 11A. FIGS. 12A to 12C depict representations of the alternative embodiment of the anti-tilt IC cooling system block pressure mount assembly of FIG. 11A. FIG. 13 depicts a cross-sectional view of an embodiment of the block housing of the anti-tilt IC cooling system block pressure mount assembly of FIG. 12A. Referring to FIGS. 11A to 13, in certain embodiments, the clamping assembly comprises a clamp 330 having a pair of central cam wheels 336, 336. Each pair of central cam wheels 336, 336 has a central pivot channel 337, 337 therethrough and a central handle 335. The central handle 335 is connected and extended outwardly from the pair of central cam wheels 336, 336. In certain embodiments, the reinforcing assembly comprises a pre-bent plate 368, a central head pin 369, and a spring 361. The pre-bent plate 368 has a pair of central attachment members 367, 367, a first securing end portion 361, and a second securing end portion 361 opposite the first securing end portion 361. Each pair of central attachment members 367, 367 has a central attachment bore 368 therethrough and is connected and extended upwardly from a center of the pre-bent plate 368. The pre-bent plate 368 is disposed on an inner surface of the central member 365a. The first securing end portion 361 and second securing end portion 369 is fixedly attached to the central member 365a longitudinally. In particular embodiments, the central aperture 166 is substantially quadrilateral-shaped, however, the embodiments are not limited thereto. In particular embodiments, the central aperture 366 is slit-shaped, preventing dust or debris from falling onto and/or being caught on the upper surface 999 of the packaged integrated circuit 990 when the clamping assembly is moved to the clamped position C. The pair of central attachment members 367, 367 protrude through two slits of the central aperture 366. The clamp 330 is rotatably attached between the pair of central attachment members 367, 367 via attachment of the central head pin 369 to each central attachment bore 368 and through each central pivot channel 337, 337 and the spring 361. The spring 361 is tensioned, such that, when the clamping assembly is in the clamped position C, the clamping assembly is forced against an upper surface of the central member 365a. When the clamping assembly is in the ready position R, a first distance D1a from the central pivot channel 337, 337 to a first edge of each of the pair of central cam wheels 336, 336 is greater than a second distance D2a from the central pivot channel 337, 337 to a second edge of each of the pair of central cam wheels 336, 336, wherein the pre-bent plate 368 is lifted toward the central member 365a. When the clamping assembly is moved to the clamped position C, the pre-bent plate 368 is lowered away from the inner surface of the central member 365a. The clamp 330 of the clamping assembly distributes the uniform compressive load through the pre-bent plate 368 to the upper surface 999 of the packaged integrated circuit 990 and the spring 361 of the reinforcing assembly, friction loads the clamp 330 of the clamping assembly to retain the clamping assembly in place.

Like elements and features of the anti-tilt IC cooling system block pressure mount assembly 300 adapted for mounting an IC cooling system block 980, 920 having a bottom surface 988, (not shown) to an upper surface 999 of a packaged integrated circuit 990, the packaged integrated circuit 990 mounted to a substrate 991, the substrate 991 mounted to a socket 992, the socket 992 mounted to a circuit board 993, comprising the block housing 160 and plurality of attachment members 140, 141 is as described previously in the embodiments of the anti-tilt IC cooling system block pressure mount assembly 100, as an example and not to be limiting, such as the pair of outwardly facing L-shaped flange legs 164, and for sake of brevity, will not be repeated hereafter.

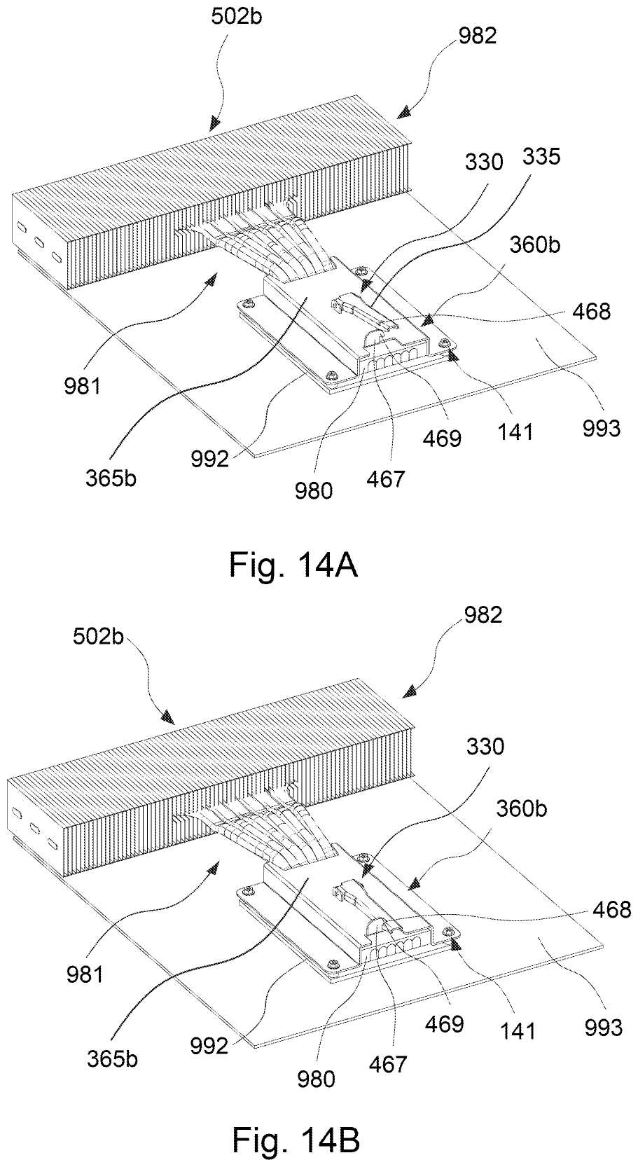

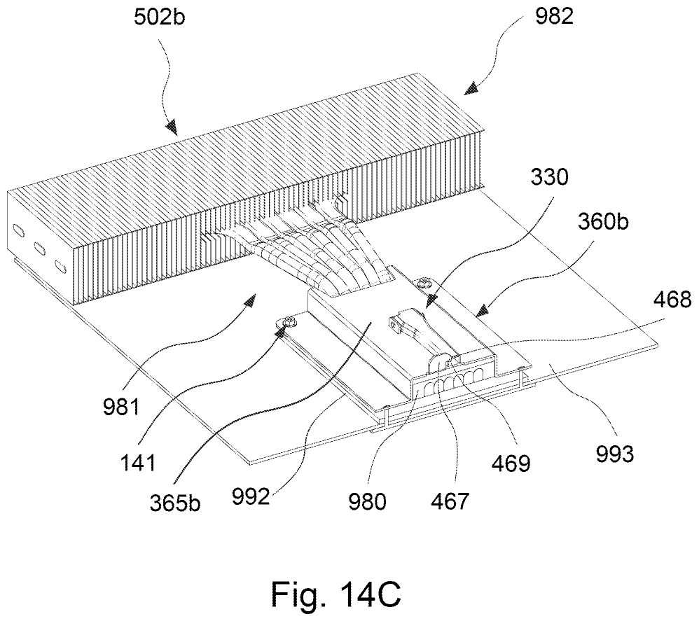

FIG. 14A depicts a representation of an alternative embodiment of an anti-tilt IC cooling system block pressure mount assembly, securing an IC cooling system block of an IC cooling system mounted to a circuit board of FIG. 11A. FIGS. 14B and 14C depict another representation and a view of the alternative embodiment of an anti-tilt IC cooling system block pressure mount assembly, clamping an IC cooling system block of an IC cooling system mounted to a circuit board of FIG. 11A. Referring to FIGS. 14A and 14B and referring to FIGS. 11A to 13 and FIGS. 1A to 2B, the clamping assembly comprises the clamp 330 having the pair of central cam wheels 336, 336. Each pair of central cam wheels 336, 336 has the central pivot channel 337, 337 therethrough and the central handle 335. The central handle 335 is connected and extended outwardly from the pair of central cam wheels 336, 336. In certain embodiments, the reinforcing assembly comprises the pre-bent plate 368, the central head pin 369, and the spring 361. The pre-bent plate 368 has the pair of central attachment members 367, 367, the first securing end portion 361, and the second securing end portion 361 opposite the first securing end portion 361. Each pair of central attachment members 367, 367 has the central attachment bore 368 therethrough and is connected and extended upwardly from a center of the pre-bent plate 368. The pre-bent plate 368 is disposed on an inner surface of the central member 365a. The first securing end portion 361 and second securing end portion 369 is fixedly attached to the central member 365a longitudinally. The pair of central attachment members 367, 367 protrude through two slits of the central aperture 366. The clamp 330 is rotatably attached between the pair of central attachment members 367, 367 via attachment of the central head pin 369 to each central attachment bore 368 and through each central pivot channel 337, 337 and the spring 361. The spring 361 is tensioned, such that, when the clamping assembly is in the clamped position C, the clamping assembly is forced against an upper surface of the central member 365a. In particular embodiments, the central member 365b further comprises a locking member 467 having a hook 469. The locking member 467 is connected and extended upwardly from the upper surface of the central member 365b near to an end of the central member 365b. In particular embodiments, the central handle 335 of the clamp 330 comprises a catch opening 468. When the clamping assembly is in the ready position R, a first distance D1a from the central pivot channel 337, 337 to a first edge of each of the pair of central cam wheels 336, 336 is greater than a second distance D2a from the central pivot channel 337, 337 to a second edge of each of the pair of central cam wheels 336, 336, wherein the pre-bent plate 368 is lifted toward the central member 365a. When the clamping assembly is moved to the clamped position C, the pre-bent plate 368 is lowered away from the inner surface of the central member 365a. The clamp 330 of the clamping assembly distributes the uniform compressive load through the pre-bent plate 368 to the upper surface 999 of the packaged integrated circuit 990 and the spring 361 of the reinforcing assembly, friction loads the clamp 330 of the clamping assembly to retain the clamping assembly in place.

The locking member 467 acts as an arm of a latch, that extends upwardly from the central member 365b. The catch opening 468 functions like a catch that catches the hook 469 when the clamping assembly is in the clamped position C.

Like elements and features of the anti-tilt IC cooling system block pressure mount assembly 502b adapted for mounting an IC cooling system block 980, 920 having a bottom surface 988, (not shown) to an upper surface 999 of a packaged integrated circuit 990, the packaged integrated circuit 990 mounted to a substrate 991, the substrate 991 mounted to a socket 992, the socket 992 mounted to a circuit board 993, comprising the block housing 100, 360a and plurality of attachment members 140, 141 is as described previously in the embodiments of the anti-tilt IC cooling system block pressure mount assembly 100, 300, as an example and not to be limiting, such as the pair of outwardly facing L-shaped flange legs 164, and for sake of brevity, will not be repeated hereafter.

Those of ordinary skill in the relevant art may readily appreciate that the locking member 467 having the hook 469 and catch opening 468 of the clamp 330 may be any type and/or combination of latching mechanisms and may be disposed along any portion of the central member 165, 365a, 365b and handle 135, 365 of the clamp 130, 330 and the embodiments are not limited thereto. As long as at least one of the clamping assembly, plurality of attachment members 140, 141, reinforcing assembly of the central member 165, 365a, 365b, or any combination of the foregoing is adapted to be friction loaded, whereby when the clamping assembly is in the clamped position C, the clamping assembly is retained in place.

In the embodiments, the block housing 160, 260a, 260b, 360a, 360b and clamping assembly comprises at least one of a copper material, a nickel material, a stainless-steel material, a titanium material, an aluminum material, or any combination of the foregoing, or a polymeric compound material, a ceramic material, or a metal and ceramic composite material.

In an embodiment, anti-tilt pressure mount assembly 100, 201, 202, 300 adapted for mounting an IC cooling system block 980, 920 having a bottom surface 988, (not shown) to an upper surface 999 of a packaged integrated circuit 990, the packaged integrated circuit 990 mounted to a substrate 991, the substrate 991 mounted to a socket 992, the socket 992 mounted to a circuit board 993, comprising a block housing 160, 260a, 260b, 360a, 360b having a central member 165, 265a, 265b, 365a, 365b and pair of outwardly facing L-shaped flange legs 164, clamping assembly having ready and clamped positions R, C, and plurality of attachment members 140, 141 is provided. The central member 165, 265a, 265b, 365a, 365b has a central aperture 166, 266a, 266b, 366 disposed through the central member 165, 265a, 265b, 365a, 365b, and a reinforcing assembly disposed near to the central aperture 166, 266a, 266b, 366. The pair of outwardly facing L-shaped flange legs 164 is connected and extended downwardly from respective opposing ends of the central member 165, 265a, 265b, 365a, 365b. Each pair of outwardly facing L-shaped flange legs 164 has a connected end portion 163 connected to the central member 165, 265a, 265b, 365a, 365b and a non-connected end portion 162 opposite the connected end portion 163. Each non-connected end portion 162 has a pair of side bores 400 disposed through the non-connected end portion 162 at respective opposing ends of the non-connected end portion 162. The clamping assembly is attached to the reinforcing assembly and has a ready position R and a clamped position C. The clamped position C clamps the bottom surface 988 of the IC cooling system block 980, 920 to the upper surface 999 of the packaged integrated circuit 990. Each of the plurality of attachment members 140, 141 is received through each pair of side bores 400, securing the anti-tilt pressure mount assembly 100, 201, 202, 300 housing the IC cooling system block 980, 920 therein to the socket 992 and circuit board 993. When the plurality of attachment members 140, 141 are secured to the socket 992 and circuit board 993 and the clamping assembly is in the ready position R, the IC cooling system block 980, 920 is not clamped to the packaged integrated circuit 990 and the IC cooling system block 980, 920 is removable from or placeable within the anti-tilt pressure mount assembly 100, 201, 202, 300. When the plurality of attachment members 140, 141 are secured to the socket 992 and circuit board 993 and the clamping assembly is moved to the clamped position C, a compressive load is uniformly distributed to the upper surface 999 of the packaged integrated circuit 990, whereby the bottom surface 988 of the IC cooling system block 980, 920 is only in thermal contact with the upper surface 999 of the packaged integrated circuit 990.

The block housing 160, 260a, 260b, 360a, 360b of the anti-tilt pressure mount assembly 100, 201, 202, 300, housing a heat spreader block 980 or a water block and pump unit 920 therein, is secured to the socket 992 and circuit board 993, whereby the heat spreader block 980 or water block and pump unit 920 is not clamped to the packaged integrated circuit 990 and the heat spreader block 980 or water block and pump unit 920 is removable from or placeable within the anti-tilt pressure mount assembly 100, 201, 202, 300. The clamping assembly clamps the bottom surface 988 of the heat spreader block 980 or water block and pump unit 920 to the upper surface 999 of the packaged integrated circuit 990, whereby a uniform compressive load is distributed to the upper surface 999 of the packaged integrated circuit 990 via spring loaded screws through a pair of cam wheels 136, 136, an adjustable member 230 through a pair of protruding members, the adjustable member 230, or a clamp 130, 330 through a pre-bent plate 268a, 268b, 368. Thus, no excessive tilt forces are distributed to the upper surface 999 of the packaged integrated circuit 990 via sequential screwing or fastening, during assembly, thereby mitigating strain on solder balls of the packaged integrated circuit 990 and potential shearing of the electrical and physical connection of the packaged integrated circuit 990 to the circuit board 993. No structure is assembled to the socket 992 and circuit board 993 to rigidly support the heat spreader block 980 or water block and pump unit 920. The bottom surface 988 of the heat spreader block 980 or water block and pump unit 920 is in thermal contact with the upper surface 999 of the packaged integrated circuit 990, transporting heat away therefrom. Thus, weight, size, number of parts, and complexity of the IC cooling system assembly is decreased. At least one of the clamping assembly or plurality of attachment members 140, 141 is adapted to adjust a clamping distance of the housed heat spreader block 980 or a water block and pump unit 920 or a height of the anti-tilt pressure mount assembly 100, 201, 202, 300 secured to the socket 992 and circuit board 993, respectively, whereby a same compressive load is uniformly distributed to upper surfaces of different packaged integrated circuits having different thicknesses. Thus, excessive forces due to standardized structures and height variation of the packaged integrated circuits during packaging or poor thermal contact between the bottom surface 988 of the heat spreader block 980 or water block and pump unit 920 and upper surface 999 of the packaged integrated circuit 990 is mitigated, respectively, thereby mitigating strain on solder balls of the packaged integrated circuit 990 and potential shearing of the electrical and physical connection of the packaged integrated circuit 990 to the circuit board 993 or poor thermal contact between the heat spreader block 980 or water block and pump unit 920 and the packaged integrated circuit 990.

The presently disclosed inventive concepts are not intended to be limited to the embodiments shown herein, but are to be accorded their full scope consistent with the principles underlying the disclosed concepts herein. Directions and references to an element, such as “up,” “down,”, “upper,” “lower,” “horizontal,” “vertical,” “left,” “right,” and the like, do not imply absolute relationships, positions, and/or orientations. Terms of an element, such as “first” and “second” are not literal, but, distinguishing terms. As used herein, terms “comprises” or “comprising” encompass the notions of “including” and “having” and specify the presence of elements, operations, and/or groups or combinations thereof and do not imply preclusion of the presence or addition of one or more other elements, operations and/or groups or combinations thereof. Sequence of operations do not imply absoluteness unless specifically so stated. Reference to an element in the singular, such as by use of the article “a” or “an”, is not intended to mean “one and only one” unless specifically so stated, but rather “one or more”. As used herein, “and/or” means “and” or “or”, as well as “and” and “or.” As used herein, ranges and subranges mean all ranges including whole and/or fractional values therein and language which defines or modifies ranges and subranges, such as “at least,” “greater than,” “less than,” “no more than,” and the like, mean subranges and/or an upper or lower limit. All structural and functional equivalents to the elements of the various embodiments described throughout the disclosure that are known or later come to be known to those of ordinary skill in the relevant art are intended to be encompassed by the features described and claimed herein. Moreover, nothing disclosed herein is intended to be dedicated to the public regardless of whether such disclosure may ultimately explicitly be recited in the claims. No element or concept disclosed herein or hereafter presented shall be construed under the provisions of 35 USC 112f unless the element or concept is expressly recited using the phrase “means for” or “step for”.

In view of the many possible embodiments to which the disclosed principles can be applied, we reserve the right to claim any and all combinations of features and acts described herein, including the right to claim all that comes within the scope and spirit of the foregoing description, as well as the combinations recited, literally and equivalently, in the following claims and any claims presented anytime throughout prosecution of this application or any application claiming benefit of or priority from this application.

What is claimed is:

1. An anti-tilt pressure mount assembly adapted for mounting an IC cooling system block having a bottom surface to an upper surface of a packaged integrated circuit, the packaged integrated circuit mounted to a circuit board, comprising:
a block housing adapted to house the IC cooling system block therein, comprising:
a central member having a central aperture disposed through the central member, and a reinforcing assembly disposed near to the central aperture; and
a pair of outwardly facing L-shaped flange legs connected and extended downwardly from respective opposing ends of the central member, each pair of outwardly facing L-shaped flange legs having a connected end portion connected to the central member and a non-connected end portion opposite the connected end portion, each non-connected end portion having a pair of side bores disposed through the non-connected end portion at respective opposing ends of the non-connected end portion;
a clamping assembly attached to the reinforcing assembly having a ready position and a clamped position, the clamped position clamps the bottom surface of the IC cooling system block to the upper surface of the packaged integrated circuit; and
a plurality of attachment members, each received through each pair of side bores, securing the anti-tilt pressure mount assembly housing the IC cooling system block therein to the circuit board,
wherein when the plurality of attachment members are secured to the circuit board and the clamping assembly is in the ready position, the IC cooling system block is not clamped to the packaged integrated circuit, and
wherein when the plurality of attachment members are secured to the circuit board and the clamping assembly is moved to the clamped position, a compressive load is uniformly distributed to the upper surface of the packaged integrated circuit, whereby the bottom surface of the IC cooling system block is only in thermal contact with the upper surface of the packaged integrated circuit.

2. The anti-tilt pressure mount assembly of claim 1, wherein when the clamping assembly is in the ready position, the bottom surface of the IC cooling system block is parallel with the upper surface of the packaged integrated circuit.

3. The anti-tilt pressure mount assembly of claim 1, wherein at least one of the clamping assembly or plurality of attachment members is adapted to adjust a clamping distance of the housed IC cooling system block or a height of the anti-tilt pressure mount assembly secured to the circuit board, respectively, whereby a same compressive load is uniformly distributed to upper surfaces of different packaged integrated circuits having different thicknesses.

4. The anti-tilt pressure mount assembly of claim 1, wherein at least one of the clamping assembly, plurality of attachment members, reinforcing assembly of the central member, or any combination of the foregoing is adapted to be friction loaded, whereby when the clamping assembly is in the clamped position, the clamping assembly is retained in place.

5. The anti-tilt pressure mount assembly of claim 4, wherein the clamping assembly comprises a clamp having a pair of cam wheels, each pair of cam wheels having a pivot channel therethrough, and a handle, the handle is connected and extended outwardly from the pair of cam wheels, and the reinforcing assembly comprises a pair of attachment members, each pair of attachment members has an attachment bore therethrough, and a head pin, the pair of attachment members is connected and extended upwardly from respective opposing ends of the central aperture of the central member, the clamp is rotatably attached between the pair of attachment members via attachment of the head pin to each attachment bore and through each pivot channel, and the plurality of attachment members comprise spring loaded screws, whereby when the clamping assembly is in the ready position, a first distance from the pivot channel to a first edge of each of the pair of cam wheels is less than a second distance from the pivot channel to a second edge of each of the pair of cam wheels, and when the clamping assembly is moved to the clamped position, the pair of cam wheels rotates through the central aperture and protrudes through a plane of the central member, whereby the spring loaded screws of the plurality of attachment members distribute the uniform compressive load to the upper surface of the packaged integrated circuit via the pair of cam wheels, and the spring loaded screws of the plurality of attachment members and an inner tilt angle of each of the pair of cam wheels of the clamping assembly, friction loads the clamp of the clamping assembly to retain the clamping assembly in place.

6. The anti-tilt pressure mount assembly of claim 4, wherein the clamping assembly comprises an adjustable member having a knurled head and a cylindrical base having male threads thereon, a cylindrical groove, and a flat base, and a securing ring, the cylindrical base connected and extending outwardly from the knurled head, the flat base disposed opposite the knurled head, and the cylindrical groove disposed near to the flat base, and the securing ring is removably attached to the cylindrical groove, and the reinforcing assembly comprises a pre-bent plate having a central plate bore and a first securing end portion and second securing end portion opposite the first securing end portion, the first securing end portion and second securing end portion is fixedly attached to the central member longitudinally, whereby the central plate bore is aligned with the central aperture of the central member and the cylindrical base is rotatably attached to the central aperture via female threads on the central aperture and protrudes through a plane of the central member and through the central plate bore, whereby when the clamping assembly is in the clamped position, the clamping assembly distributes the uniform compressive load to the upper surface of the packaged integrated circuit and the pre-bent plate of the reinforcing assembly of the central member, friction loads the adjustable member of the clamping assembly to retain the clamping assembly in place.

7. The anti-tilt pressure mount assembly of claim 6, wherein the pre-bent plate is disposed on an inner surface of the central member and the pre-bent plate further comprises a pair of central protruding members connected and extended downwardly from respective opposing sides of the central plate bore, the securing ring is disposed flush against the pre-bent plate, whereby when the clamping assembly is in the clamped position, the adjustable member of the clamping assembly distributes the uniform compressive load through the pair of central protruding members to the upper surface of the packaged integrated circuit and the pre-bent plate of the reinforcing assembly of the central member, friction loads the adjustable member of the clamping assembly to retain the clamping assembly in place.

8. The anti-tilt pressure mount assembly of claim 6, wherein the pre-bent plate is disposed on an upper surface of the central member, whereby when the clamping assembly is in the clamped position, the adjustable member of the clamping assembly distributes the uniform compressive load through the member bottom surface to the upper surface of the packaged integrated circuit and the pre-bent plate of the reinforcing assembly of the central member, friction loads the adjustable member of the clamping assembly to retain the clamping assembly in place.

9. The anti-tilt pressure mount assembly of claim 4, wherein the clamping assembly comprises a clamp having a pair of central cam wheels, each pair of central cam wheels having a central pivot channel therethrough, and a central handle, the central handle is connected and extended outwardly from the pair of central cam wheels, and the reinforcing assembly comprises a pre-bent plate having a pair of central attachment members, each pair of central attachment members has a central attachment bore therethrough, a first securing end portion, and a second securing end portion opposite the first securing end portion, a central head pin, and a spring, the pair of central attachment members is connected and extended upwardly from a center of the pre-bent plate, the pre-bent plate is disposed on an inner surface of the central member, the first securing end portion and second securing end portion is fixedly attached to the central member longitudinally, and the pair of central attachment members protrude through the central aperture, the clamp is rotatably attached between the pair of central attachment members via attachment of the central head pin to each central attachment bore and through each central pivot channel and the spring, whereby when the clamping assembly is in the ready position, a first distance from the central pivot channel to a first edge of each of the pair of central cam wheels is greater than a second distance from the central pivot channel to a second edge of each of the pair of central cam wheels, wherein the pre-bent plate is lifted toward the central member, and when the clamping assembly is moved to the clamped position, the pre-bent plate is lowered away from the central member, whereby the clamp of the clamping assembly distributes the uniform compressive load via the pre-bent plate to the upper surface of the packaged integrated circuit and the spring of the reinforcing assembly, friction loads the adjustable member of the clamping assembly to retain the clamping assembly in place.

10. The anti-tilt pressure mount assembly of claim 1, wherein a dimension of the bottom surface of the IC cooling system block is larger than a dimension of the upper surface of the packaged integrated circuit, and no structure is assembled to the circuit board to rigidly support the IC cooling system block in thermal contact with the upper surface of the packaged integrated circuit.

11. The anti-tilt pressure mount assembly of claim 1, wherein a dimension of an upper surface of the IC cooling system block is substantially similar to a dimension of the central member and a height of each of a pair of longitudinal side surfaces of the IC cooling block is smaller than a height of each connected end portion of the pair of outwardly facing L-shaped flange legs.

12. The anti-tilt pressure mount assembly of claim 1, wherein the IC cooling system block, is an IC cooling system block of an IC cooling system, and the IC cooling system is a heat pipe-heat sink-cooling system or a liquid-cooling system, and the IC cooling system block is a heat spreader block or a water block and pump unit, respectively.

13. The anti-tilt pressure mount assembly of claim 12, wherein the heat pipe-heat sink-cooling system further comprises a fin stack, and a plurality of heat pipes, each plurality of heat pipes has working fluid therein and has an evaporator end portion, a condenser end portion opposite the evaporator end portion, and a transporting end portion between the evaporator end portion and condenser end portion, each evaporator end portion is joined parallelly to the heat spreader block and each condenser end portion is joined parallelly to the fin stack, whereby the bottom surface of the heat spreader block having the evaporator end portion joined thereto, is in thermal contact with the upper surface of the packaged integrated circuit, absorbing heat therefrom, vaporizing the working fluid in the evaporator end portion, transporting heated steam away to the condenser end portion joined to the fin stack, dissipating heat to the ambient, and condensing the vapor back to working fluid, and then returning the working fluid to the evaporator end portion through capillary action, repeating a continuous heat dissipation cyclical process.

14. The anti-tilt pressure mount assembly of claim 12, wherein the liquid-cooling system further comprises a radiator, a first conduit, a second conduit, and working fluid, the first conduit has a water block and pump unit first conduit end communicating with the water block and pump unit and a radiator first conduit end opposite the water block and pump unit first conduit end communicating with the radiator, and the second conduit has a water block and pump unit second conduit end communicating with the water block and pump unit and a radiator second conduit end opposite the water block and pump second conduit end communicating with the radiator, whereby the water block and pump unit, first and second conduits, and radiator form a closed-loop liquid-cooling system having working fluid therein, and whereby the bottom surface of the water block and pump unit, is in thermal contact with the upper surface of the packaged integrated circuit, transporting heat away therefrom, and then working fluid, circulating inside of the closed-loop liquid-cooling system, flows over the water block and pump unit, removing heat therefrom.

15. The anti-tilt pressure mount assembly of claim 14, wherein the radiator has a fan mounted to a side of the radiator.

16. The anti-tilt pressure mount assembly of claim 1, wherein the block housing comprises at least one of a copper material, a nickel material, a stainless steel material, a titanium material, an aluminum material, or any combination of the foregoing, or a polymeric compound material, a ceramic material, or a metal and ceramic composite material.

17. The anti-tilt pressure mount assembly of claim 1, wherein the clamping assembly comprises at least one of a copper material, a nickel material, a stainless steel material, a titanium material, an aluminum material, or any combination of the foregoing, or a polymeric compound material, a ceramic material, or a metal and ceramic composite material.
